(19) United States
(12) Patent Application Publication
(10) Pub. No.: US 2025/0274036 A1
(43) Pub. Date: Aug. 28, 2025

(54) DC LINK SNUBBER DEVICE CONFIGURED FOR CONNECTION TO A POWER MODULE AND/OR THE LIKE AND PROCESSES OF IMPLEMENTING THE SAME

(71) Applicant: WOLFSPEED, INC., Durham, NC (US)

(72) Inventor: Kirill KLEIN, Berlin (DE)

(21) Appl. No.: 18/589,080

(22) Filed: Feb. 27, 2024

(51) Int. Cl. H02M 1/34; H05K 7/20

(52) U.S. Cl. CPC H02M 1/34; H05K 7/20254

(57) ABSTRACT

A snubber device includes a snubber assembly, a snubber circuit including at least one snubber capacitor, and moreover includes a snubber substrate. The snubber device also includes where the snubber device is configured to be arranged outside and separate from a power module.

### BACKGROUND OF THE DISCLOSURE

As will be appreciated by those skilled in the art, power modules are known in various forms. Power modules provide a physical containment for power components, usually power semiconductor devices. The power module typically carries the power semiconductor devices, provides electrical and thermal contact, and includes electrical insulation.

In operation, the power semiconductor devices are controlled to turn-on and turn-off in order to control delivery of current through the power module. However, the turn-off speed of hard switching in power modules is often limited by a power loop inductance. During fast switching off of the current, the stray inductances within the switching cell create voltage overshoot over the power semiconductor devices. The voltage overshoot is in superposition with static operation voltage and can reach voltages above safe operating area of the semiconductor. To solve this, the turn-off speed is reduced to keep the power module, as well as the power semiconductor devices, within a safe operating area. This solution however increases switching losses in the power module, which limits a value and usefulness of fast switching semiconductor technologies such as SiC MOSFETS.

Accordingly, a device and process are needed to increase switching speed in power modules, reduce switching losses in power modules, and/or the like.

### SUMMARY OF THE DISCLOSURE

The foregoing needs are met, to a great extent, by the disclosure, wherein in one aspect a DC link snubber device is configured for connection to a power module and/or the like and processes of implementing the same are provided.

In one aspect, a snubber device includes a snubber assembly. The snubber device in addition includes a snubber circuit having at least one snubber capacitor. The snubber device moreover includes a snubber substrate. The snubber device also includes where the snubber assembly is configured to be arranged outside and separate from the power module.

In one aspect, a snubber device includes a snubber assembly. The snubber device in addition includes a snubber circuit having at least one snubber capacitor. The snubber device moreover includes a snubber substrate. The snubber device also includes where the snubber device is configured to connect to power module interconnects that connect the snubber device to the power module. The snubber device further includes where the snubber device is configured to connect to capacitor interconnects that connect the snubber device to the at least one DC link capacitor.

In one aspect, a snubber device includes a snubber assembly. The snubber device in addition includes a snubber circuit having at least one snubber capacitor. The snubber device moreover includes a snubber substrate. The snubber device also includes where at least the at least one snubber capacitor is configured to be arranged outside and separate from the power module.

In one aspect, a process includes providing a snubber assembly. The process in addition includes providing a snubber circuit having at least one snubber capacitor. The process moreover includes providing a snubber substrate. The process also includes configuring and arranging the snubber assembly outside and separate from the power module.

In one aspect, a process includes providing a snubber assembly. The process in addition includes providing a snubber circuit having at least one snubber capacitor. The process moreover includes providing a snubber substrate. The process also includes configuring and arranging the snubber device to connect to power module interconnects that connect the snubber device to the power module. The process further includes configuring and arranging the snubber device to connect to connect to capacitor interconnects that connect the snubber device to the at least one DC link capacitor.

In one aspect, a process includes providing a snubber assembly. The process in addition includes providing a snubber circuit having at least one snubber capacitor. The process moreover includes providing a snubber substrate. The process also includes configuring and arranging at least the at least one snubber capacitor outside and separate from the power module.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates an exemplary schematic of a snubber device implemented in a power system according to aspects of the disclosure.

FIG. 2 illustrates another exemplary schematic of a snubber device implemented in a power system according to aspects of the disclosure.

FIG. 3 illustrates an exemplary implementation of the snubber device according to aspects of the disclosure.

FIG. 4 includes FIG. 4A, FIG. 4B, and FIG. 4C that illustrate three exemplary schematics of the DC snubber circuit according to aspects of the disclosure.

FIG. 5 illustrates a partial upper perspective view of an exemplary implementation of the snubber device according to aspects of the disclosure.

FIG. 6 illustrates a further partial upper perspective view of the exemplary implementation of the snubber device according to FIG. 5.

FIG. 7 illustrates a partial upper perspective view of another exemplary implementation of the snubber device according to aspects of the disclosure.

FIG. 8 illustrates a further partial upper perspective view of the another exemplary implementation of the snubber device according to FIG. 7.

FIG. 9 illustrates an exemplary implementation of a power module according to aspects of the disclosure.

FIG. 10 illustrates another exemplary implementation of a power module according to aspects of the disclosure.

### DETAILED DESCRIPTION

The disclosure will now be described with reference to the drawing figures, in which like reference numerals refer to like parts throughout. Aspects of the disclosure advantageously provide a DC link snubber device configured for connection to a power module and/or the like and processes of implementing the same.

The disclosed device may be a configuration and/or structure that may be placed between the power module and a DC link capacitor. This structure may be configured to provide a low-inductance connection between the DC-link capacitor and the power module with snubber and cooling functions. The disclosed device may enable the power module to implement higher speed hard switching. Additionally, the disclosed device may be implemented separate from the power module. Accordingly, because the disclosed device is not part of the power module, the disclosed device may not impact qualification of the power module.

The disclosed device may be configured to be located outside the power module. Moreover, the disclosed device may implement a DC link snubber circuit. Further, the disclosed device may be configured with a low-inductance interconnection to the power module.

Aspects of the disclosed device may provide proper damping, suitable cooling through, for example a heat-sink, low-inductive interconnection to the power module and high ripple current capability. In this regard, the disclosed device may add an arrangement between the DC link capacitor and the power module. Further, the disclosed device may be implemented separate from the power module. Accordingly, the disclosed device may not affect conventional qualification procedures of the power module.

Further, the disclosed device may be configured to be implemented with a low-inductive bus bar interconnection to the power module. In aspects, the low-inductive bus bar interconnection may be optimized for certain implementations of the power module. Additionally, the disclosed device may implement a DC link snubber circuit.

In aspects, the DC link snubber circuit may implement at least one capacitor. In aspects, the capacitor may be implemented with higher equivalent series resistance (ESR) than a typical Multilayer Ceramic Capacitor (MLCC), a resistor-capacitor circuit (RC circuit), a Resistor, Capacitor, Diode (RCD) circuit, and/or the like. Moreover, the DC link snubber circuit may be configured considering the interconnection to the DC link capacitor.

In aspects, the disclosed device may be configured to be well cooled. Further, the implementation of the capacitor with a higher ESR may substantially damp oscillations. In this regard, energy from oscillations may heat up the DC link snubber. Therefore, it may be beneficial for the DC link snubber circuit to be cooled.

Due to the fact, that the capacitance value used in the DC link snubber may be much lower than in a large capacitance value (LCV) DC link capacitor, the disclosed device implementing the DC link snubber may be geometrically smaller. Accordingly, the disclosed device may be placed: (a) low-inductively close to the power module; and/or (b) on a heat sink beside the power module.

In current implementations, if an internal ohmic resistance, also called equivalent series resistance (ESR), of the LCV DC link capacitor is reduced, then in the switching moment of the oscillation may not be damped and may cause significant oscillations between power module and the LCV DC link capacitor, generate electromagnetic interference issues, and/or the like. Moreover, in current implementations without the disclosed device, an expensive LCV DC link capacitor with (1) advanced low-inductance connection to the power module, (2) high ripple current capability and (3) proper cooling connection is required. In this regard, cooling such capacitor implementations are greatly complicated by the required expensive and bulky foil capacitors. Moreover, keeping the LCV DC link capacitor cool may be critical for its lifetime/failure rate and electrical performance. Additionally, placing a DC link snubber in the power module would significantly complicate qualification of the power module. A further disadvantage is that the low-inductive low-ESR LCV DC link capacitors may cause high di/dt (rate of current change) in a short-circuit case.

Accordingly, the disclosed device addresses these issues. In particular, to address the issues and requirements of proper current damping, good cooling to a heat-sink, low-inductive interconnection to the power module, high ripple current capability, and/or the like, the disclosure proposes to add a structure between a large value capacitance DC link capacitor and the power module with one or more of the following features: the disclosed device may be separate from the power module, therefore does not affect conventional qualification procedure of the power module; the disclosed device may implement a low-inductive bus bar interconnection to the power module, which is optimized for certain power module implementations; the disclosed device may contain inside a DC link snubber circuit. For example, the DC link snubber circuit may implement a capacitor with higher ESR than a typical MLCC, RC circuit, RCD circuit. Further, the DC link snubber circuit may be configured in consideration of the interconnection to the DC link capacitor; and the disclosed device may be well cooled. Moreover, implementation of the disclosed device allows for implementation of lower cost LCV DC link capacitors. Further, implementation of the disclosed device allows for implementation of lower cost LCV DC link capacitors without high ripple current capability. Additionally, implementation of the disclosed device may reduce the necessity to provide cooling for the LCV DC link capacitors.

In this regard, the higher ESR capacitor may substantially damp the oscillations. The energy from the oscillations may heat up the DC link snubber circuit. Therefore, the DC link snubber circuit may be cooled. Due to the fact that the capacitance value used in the DC link snubber circuit is much lower than in the LCV DC link capacitor, the DC link snubber circuit may be geometrically small and may be placed in a number of different arrangements. For example, the DC link snubber circuit may be arranged: (a) low-inductively close to the power module; and/or (b) on the heat sink beside the power module.

For high voltage applications, such as applications greater than 60 V, the DC link snubber circuit may be isolated from the heatsink providing safety insulation. For this purpose, the DC link snubber circuit may be placed on a high thermally conductive, but electrically isolating substrate. For example, the substrate may be an active metal braze (AMB) substrate, a direct bond copper (DBC) substrate, an insulated metal substrate (IMS), a direct copper bonded (DCB) substrate, a direct printed copper (DPC) substrate, and/or the like.

In aspects, the disclosure relates to placement of a snubber outside of the power module in combination with a low-inductive connection to the power module and enhanced cooling. For example, the enhanced cooling may include a highly thermally conductive isolating substrate. Accordingly, the disclosed device allows for: reduction of switching losses; fast and nearly oscillation-free switching; greater flexibility of interconnection to the LCV DC link capacitor; shift some losses from the LCV DC link, which is hard to cool, to well cooled DC link snubber. In this regard, keeping the LCV DC link cool may be critical for its lifetime/failure rate and electrical performance; usage of cheaper conventional LCV DC link capacitors with lower ripple current requirements. As this requirement usually leads to higher required capacitance value of the LCV DC link capacitors, then possibly reducing a minimal required capacitance value of the DC link capacitor to be a reduced capacitance value (RCV) DC link capacitor; shift some switching energy from power semiconductors to the DC link snubber and therefore give additional thermal headroom for the power semiconductors; thermo-mechanical decoupling from the power module and potentially higher system reliability; and/or the like.

Accordingly, the disclosed device may reduce the cost of a switching cell system that includes a RCV DC link capacitor, the disclosed DC link-snubber circuit, a power module, and/or the like.

The disclosed device may be implemented in numerous applications. For example, applications with high-power hard switching systems such as a traction inverter, a solar inverter, and/or the like. Additionally, other fast switching systems may also benefit from implementations of the disclosed device.

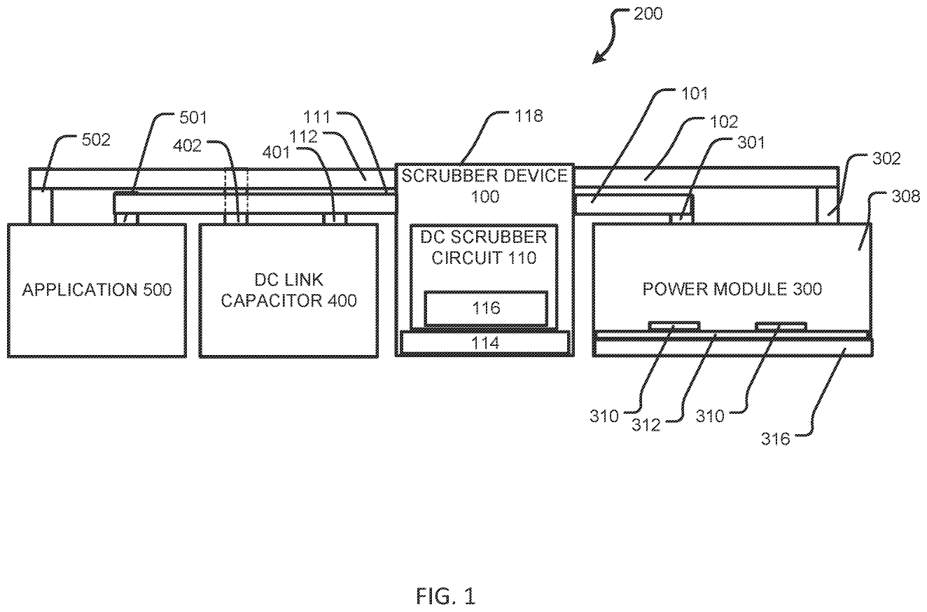

FIG. 1 illustrates an exemplary schematic of a snubber device implemented in a power system according to aspects of the disclosure.

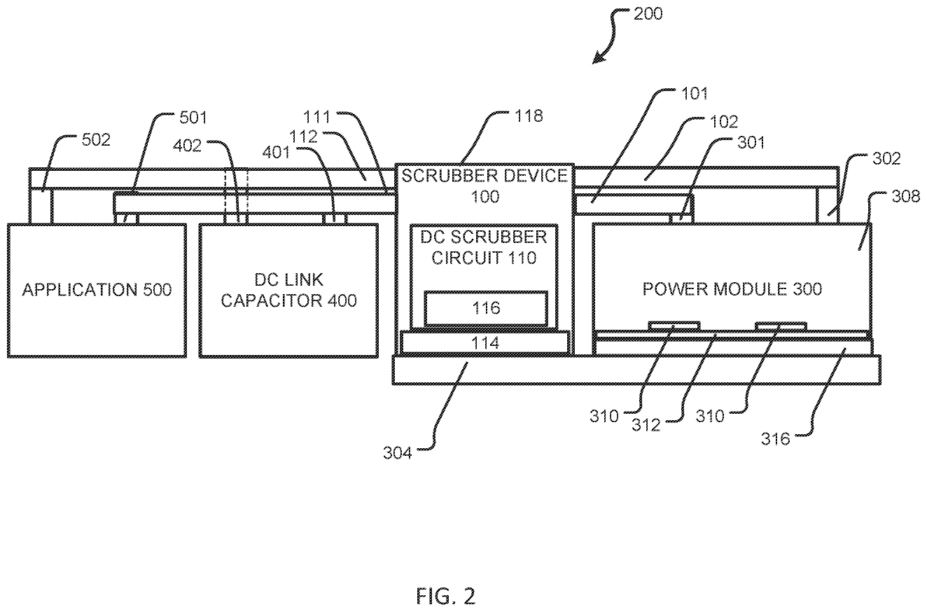

FIG. 2 illustrates another exemplary schematic of a snubber device implemented in a power system according to aspects of the disclosure.

In particular, FIG. 1 illustrates a snubber device 100 implemented in a power system 200. In aspects, the power system 200 may include a power module 300, at least one DC link capacitor 400, and/or the like. Further, the power system 200 may provide power to an application 500.

The snubber device 100 may include a snubber assembly 118, a DC snubber circuit 110, a snubber substrate 114, and/or the like. In aspects, the DC snubber circuit 110 may be configured and arranged within the snubber assembly 118. In aspects, the snubber substrate 114 may be at least partially configured and arranged within the snubber assembly 118.

In aspects, the snubber substrate 114 may be configured as a heat sink. In aspects, the snubber substrate 114 may be an active metal braze (AMB) substrate, a direct bond copper (DBC) substrate, an insulated metal substrate (IMS), a direct copper bonded (DCB) substrate, a direct printed copper (DPC) substrate, and/or the like.

In aspects, the snubber device 100 and/or the DC snubber circuit 110 may implement at least one snubber capacitor 116. In aspects, the at least one snubber capacitor 116 may be configured and arranged within the snubber assembly 118.

In aspects, the DC snubber circuit 110 may be configured as a short-term alternative current path for power semiconductor devices of the power module 300. In aspects, the DC snubber circuit 110 may include the at least one snubber capacitor 116 and further include a resistor. In aspects, the DC snubber circuit 110 include the at least one snubber capacitor 116 and may further include a diode. In aspects, the DC snubber circuit 110 may include the at least one snubber capacitor 116 and further include a resistor and a diode.

In aspects, the snubber assembly 118 may be a housing. In aspects, the snubber assembly 118 may include housing sidewalls and/or housing top surfaces. In aspects, the snubber assembly 118 may be formed of a synthetic material. In one aspect, the snubber assembly 118 may be an injection molded plastic element. The snubber assembly 118 may provide electrical insulation, voltage creepage and clearance, structural support, cavities for holding a voltage and moisture blocking encapsulation, and/or the like. In one aspect, the snubber assembly 118 may be formed in an injection molding process with reinforced high temperature plastic.

In aspects, the snubber assembly 118 may include gel encapsulation filling the snubber device 100 to provide dielectric isolation. The snubber assembly 118 may include a top portion, a bottom portion, side portions, and/or the like. However, the snubber assembly 118 may be implemented in fewer or greater number of housing portions. In one aspect, the snubber assembly 118 may be constructed of a synthetic material, a plastic material, a dielectric material, an over molded material, and/or the like. In one aspect, the snubber assembly 118 may be constructed of a plastic material. In one aspect, the snubber assembly 118 may be constructed of a plastic material that may be injection molded.

In aspects, the DC snubber circuit 110 may be configured to be in thermal communication with the snubber substrate 114. In aspects, the DC snubber circuit 110 may be configured to be arranged on the snubber substrate 114. In aspects, the DC snubber circuit 110 may be configured to be arranged directly on the snubber substrate 114. Accordingly, heat generated within the DC snubber circuit 110 may be transferred to the snubber substrate 114. Thereafter, heat within the snubber substrate 114 may be transferred from the snubber device 100.

In aspects, the at least one snubber capacitor 116 may be implemented with higher equivalent series resistance (ESR) than a typical Multilayer Ceramic Capacitor (MLCC), a resistor-capacitor circuit (RC circuit), a Resistor, Capacitor, Diode (RCD) circuit, and/or the like. In aspects, a capacitance value of the at least one snubber capacitor 116 may be related to a system current of the power system 200, an allowed voltage overshoot, and/or a stray inductance of a connection to the at least one DC link capacitor 400. In aspects, a capacitance value of the at least one snubber capacitor 116 may be selected so as to achieve faster and cleaner switching of the power module 300 while limiting ringing, limiting an overvoltage during turn-off of the current of the power devices 310 that may be caused by parasitic inductances, and/or damping oscillation while turn-on of the power devices 310 and reloading of parasitic capacitances in a switching moment. In aspects, the at least one snubber capacitor 116 may be configured to be in thermal communication with the snubber substrate 114. In aspects, the at least one snubber capacitor 116 may be configured to be arranged on the snubber substrate 114. In aspects, the at least one snubber capacitor 116 may be configured to be arranged directly on the snubber substrate 114. Accordingly, heat generated within the at least one snubber capacitor 116 may be transferred to the snubber substrate 114. Thereafter, heat within the snubber substrate 114 may be transferred from the snubber device 100.

As illustrated in FIG. 2, the snubber device 100 and/or the power module 300 may be implemented with a cold plate 304. In aspects, the cold plate 304 may be a heat sink and/or the like.

In aspects, heat generated from the power module 300 may be transferred to the cold plate 304. In aspects, the cold plate 304 may be configured and arranged such that the snubber device 100 may also arranged on a portion of the cold plate 304. Accordingly, heat within the snubber substrate 114 may be transferred from the snubber device 100 to the cold plate 304. In aspects, heat within the DC snubber circuit 110 may be transferred to the snubber substrate 114. In aspects, heat within the DC snubber circuit 110 may be transferred to the snubber substrate 114 and then to the cold plate 304. In aspects, heat within the DC snubber circuit 110 may be transferred to the cold plate 304.

In aspects, heat within the at least one snubber capacitor 116 may be transferred to the snubber substrate 114. In aspects, heat within the at least one snubber capacitor 116 may be transferred to the cold plate 304. In aspects, heat within the at least one snubber capacitor 116 may be transferred to the snubber substrate 114 and then to the cold plate 304.

In aspects, the cold plate 304 may be a high performance liquid cold plate, a heat sink, and/or the like. In aspects, the cold plate 304 may be configured to transfer waste heat away from the snubber device 100 and/or the power module 300 to another source (liquid, air, etc.). In one or more aspects, the cold plate 304 may include fluid connections. In one aspect, the fluid connections may receive a fluid source and/or deliver fluid for cooling purposes in association with the cold plate 304.

In aspects, the snubber device 100 may be configured to connect to and/or may include power module interconnects. The power module interconnects may be configured to connect the snubber device 100 to the power module 300. Accordingly, the power module 300 may provide power to the snubber device 100.

In aspects, the snubber device 100 may be configured to connect to and/or may include a first power module interconnect 101 and a second power module interconnect 102. The first power module interconnect 101 may be configured to connect the snubber device 100 to a first power module terminal 301 of the power module 300; and the second power module interconnect 102 may be configured to connect to a second power module power terminal 302 of the power module 300. Accordingly, the power module 300 may provide power to the snubber device 100 from the first power module terminal 301 and the second power module power terminal 302.

In aspects, the snubber device 100 may be configured to connect to and/or may include capacitor interconnects that may be configured to connect the snubber device 100 to the at least one DC link capacitor 400. In aspects, the capacitor interconnects may further connect the snubber device 100 to the application 500.

In aspects, the snubber device 100 may be configured to connect to and/or may include a first capacitor interconnect 111 and a second capacitor interconnect 112. The first capacitor interconnect 111 may be configured to connect the snubber device 100 to a first capacitor terminal 401 of the at least one DC link capacitor 400; and the second capacitor interconnect 112 may be configured to connect to a second capacitor terminal 402 of the at least one DC link capacitor 400. In aspects, the first capacitor interconnect 111 may be configured to connect the snubber device 100 to a first application terminal 501 of the application 500; and the second capacitor interconnect 112 may be configured to connect to a second application terminal 502 of the application 500.

In aspects, the first power module interconnect 101, the second power module interconnect 102, the first capacitor interconnect 111, and the second capacitor interconnect 112, may be implemented as busbars, wires, cables, ribbons, and/or the like. Accordingly, the snubber device 100 may provide power to the at least one DC link capacitor 400 via the first capacitor terminal 401 and the second capacitor terminal 402.

In further aspects not shown, the snubber device 100 may be configured to connect to and/or may include one or more additional capacitor interconnects to connect to one or more additional capacitor terminals of the at least one DC link capacitor 400. In further aspects not shown, the snubber device 100 may be configured to connect to and/or may include one or more additional power module interconnects to connect to one or more additional power module terminals of the power module 300.

In aspects, the first power module interconnect 101 and the second power module interconnect 102 may be configured to connect to the DC snubber circuit 110. In aspects, the first capacitor interconnect 111 and the second capacitor interconnect 112 may be configured to connect to the DC snubber circuit 110.

In aspects, the power module 300 may include a power module assembly 308, power devices 310, a power substrate 312, a baseplate 316, and/or the like. In aspects, at least the power devices 310 and the power substrate 312 are arranged within the power module assembly 308.

In aspects, the power module 300 may be implemented as a power package, a semiconductor package, a power semiconductor package, an overmolded package, a module, a power module, a power semiconductor module, a power device module, an overmolded module, a case module, a case power module, a case power semiconductor module, a case power device module, and/or the like.

In aspects, the snubber device 100 may be configured to be arranged outside and separate from the power module 300. In aspects, the snubber device 100 may be configured to be arranged outside and separate from the power module assembly 308. In aspects, the snubber device 100 may be configured to be arranged in the snubber assembly 118 separate from the power module 300 and/or the power module assembly 308.

In aspects, the DC snubber circuit 110 may be configured to be arranged outside and separate from the power module 300. In aspects, the DC snubber circuit 110 may be configured to be arranged outside and separate from the power module assembly 308. In aspects, the DC snubber circuit 110 may be configured to be arranged in the snubber assembly 118 separate from the power module 300 and/or the power module assembly 308.

In aspects, the at least one snubber capacitor 116 may be configured to be arranged outside and separate from the power module 300. In aspects, the at least one snubber capacitor 116 may be configured to be arranged outside and separate from the power module assembly 308. In aspects, the at least one snubber capacitor 116 may be configured to be arranged in the snubber assembly 118 separate from the power module 300 and/or the power module assembly 308.

In aspects, the first power module terminal 301 and the second power module power terminal 302 may be configured to be arranged in or on the power module assembly 308. In aspects, the first power module interconnect 101 and/or the second power module interconnect 102 may be configured to be arranged outside and separate from the power module 300. In aspects, the first power module interconnect 101 and/or the second power module interconnect 102 may be configured to be arranged outside and separate from the power module assembly 308.

In aspects, the first power module interconnect 101 and/or the second power module interconnect 102 may be configured with minimized inductance for clean, rapid switching events with low voltage overshoot and stable performance of the power module 300. In aspects, the first power module interconnect 101 and/or the second power module interconnect 102 may be configured to have an inductance less than 30 nH (nano Henry), 20 nH, 15 nH, 10 nH, or 5 nH. In aspects, the first power module interconnect 101 and/or the second power module interconnect 102 may be configured to have an inductance of 3 nh-30 nH, 3 nh-7 nH, 7 nh-10 nH, 10 nh-20 nH, or 10 nh-30 nH. In this regard, reducing loop inductance may result in a reduced total capacitance required on the at least one DC link capacitor 400. In aspects, the first power module interconnect 101 and/or the second power module interconnect 102 may be configured for lower switching losses, higher switching frequencies, improved controllability, and/or reduced EMI of the power module 300. In aspects, the first power module interconnect 101 and/or the second power module interconnect 102 may be configured to achieve more power dense and robust power conversion systems.

In aspects, the first power module interconnect 101 and/or the second power module interconnect 102 may have a planar construction, a flat construction, a construction with no bends, a laminated construction, a thick conductor construction, and/or the like. In aspects, the first power module interconnect 101 and/or the second power module interconnect 102 may be flat buss bars, laminated flat buss bars, flat buss bars with no bends, laminated flat buss bars with no bends, laminated bussing, may be embossed, may be embossed to form co-planar contacts to the snubber device 100 and/or the power module 300, and/or the like. In aspects, the first power module interconnect 101 and/or the second power module interconnect 102 may form contacts to the snubber device 100 and/or the power module 300 without requiring a bend, may be offset vertically, may be offset horizontally, may overlap vertically, may overlap horizontally, and/or the like.

In aspects, the first power module interconnect 101 and/or the second power module interconnect 102 may include a dielectric material such as an isolation material, a dielectric isolation film, a dielectric film, and/or the like. In aspects, the dielectric material may be implemented as a thin electrical insulator placed between the overlapping metal layers of the first power module interconnect 101 and/or the second power module interconnect 102. The dielectric film may provide dielectric insulation according to electrical safety standards. The dielectric film may be kept as thin as possible to minimize inductance. In aspects, the dielectric material may also cover tops and bottoms of the first power module interconnect 101 and/or the second power module interconnect 102 in all areas that do not require an electrical connection.

In aspects, the first capacitor interconnect 111 and/or the second capacitor interconnect 112 may be configured with minimized inductance for clean, rapid switching events with low voltage overshoot and stable performance. In aspects, the first capacitor interconnect 111 and/or the second capacitor interconnect 112 may be configured to have an inductance less than 30 nH, 20 nH, 15 nH, 10 nH, or 5 nH. In aspects, the first capacitor interconnect 111 and/or the second capacitor interconnect 112 may be configured to have an inductance of 3 nh-30 nH, 3 nh-7 nH, 7 nh-10 nH, 10 nh-20 nH, or 10 nh-30 nH. In this regard, reducing loop inductance may result in a reduced total capacitance required on the at least one DC link capacitor 400. In aspects, the first capacitor interconnect 111 and/or the second capacitor interconnect 112 may be configured for lower switching losses, higher switching frequencies, improved controllability, and reduced EMI. In aspects, the first capacitor interconnect 111 and/or the second capacitor interconnect 112 may be configured to achieve more power dense and robust power conversion systems.

In aspects, the first capacitor interconnect 111 and/or the second capacitor interconnect 112 may have a planar construction, a flat construction, a construction with no bends, a laminated construction, a thick conductor construction, and/or the like. In aspects, the first capacitor interconnect 111 and/or the second capacitor interconnect 112 may be flat buss bars, laminated flat buss bars, flat buss bars with no bends, laminated flat buss bars with no bends, laminated bussing, may be embossed, may be embossed to form co-planar contacts to the snubber device 100, the at least one DC link capacitor 400, and/or the application 500, and/or the like. In aspects, the first capacitor interconnect 111 and/or the second capacitor interconnect 112 may form contacts to the snubber device 100, the at least one DC link capacitor 400, and/or the application 500 without requiring a bend, may be offset vertically, may be offset horizontally, may overlap vertically, may overlap horizontally, and/or the like.

In aspects, the first capacitor interconnect 111 and/or the second capacitor interconnect 112 may include a dielectric material such as an isolation material, a dielectric isolation film, a dielectric film, and/or the like. In aspects, the dielectric material may be implemented as a thin electrical insulator placed between the overlapping metal layers of the first capacitor interconnect 111 and/or the second capacitor interconnect 112. The dielectric film may provide dielectric insulation according to electrical safety standards. The dielectric film may be kept as thin as possible to minimize inductance. In aspects, the dielectric material may also cover tops and bottoms of the first capacitor interconnect 111 and/or the second capacitor interconnect 112 in all areas that do not require an electrical connection.

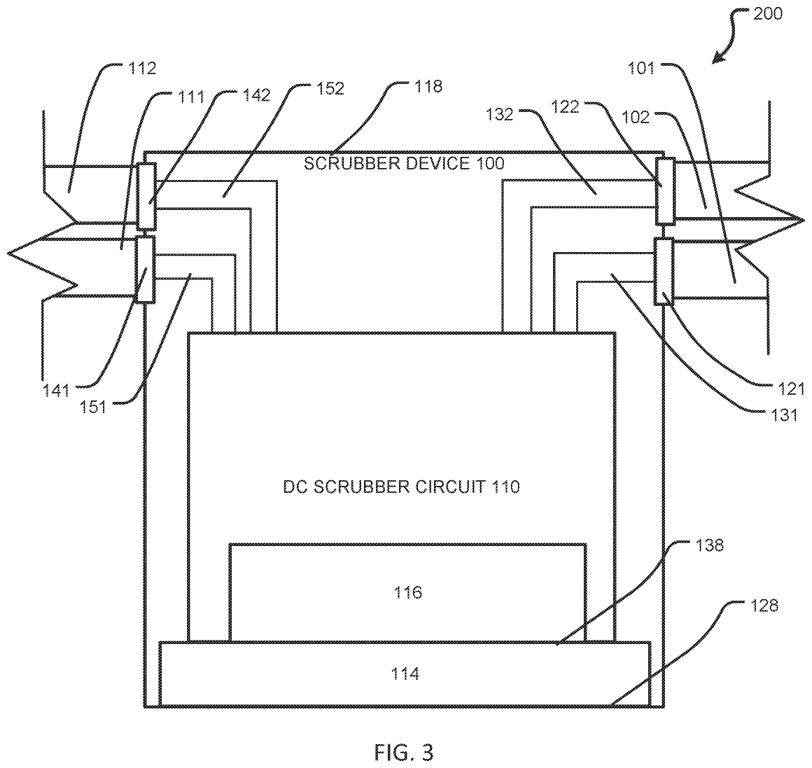

FIG. 3 illustrates an exemplary implementation of the snubber device according to aspects of the disclosure.

In particular, the snubber device 100 may include a first power terminal 121 and a second power terminal 122. The first power terminal 121 may be configured to connect the snubber device 100 to the first power module interconnect 101; and the second power terminal 122 may be configured to connect the snubber device 100 to the second power module interconnect 102. In aspects, the first power terminal 121 may be arranged on the snubber assembly 118; and the second power terminal 122 may be arranged on the snubber assembly 118. In aspects, the first power terminal 121 may provide a connection to the first power module interconnect 101 and the power module 300 and/or the first power module terminal 301; and the second power terminal 122 may provide a connection to the second power module interconnect 102 and the power module 300 and/or the second power module power terminal 302.

Further, the snubber device 100 may include a first capacitor terminal 141 and a second capacitor terminal 142. The first capacitor terminal 141 may be configured to connect the snubber device 100 to the first capacitor interconnect 111; and the second capacitor terminal 142 may be configured to connect the snubber device 100 to the second capacitor interconnect 112. In aspects, the first capacitor terminal 141 may be arranged on the snubber assembly 118; and the second capacitor terminal 142 may be arranged on the snubber assembly 118. In aspects, the first capacitor terminal 141 may provide a connection to the first capacitor interconnect 111 and the at least one DC link capacitor 400 and/or the first capacitor terminal 401; and the second capacitor terminal 142 may provide a connection to the second capacitor interconnect 112 and the at least one DC link capacitor 400 and/or the second capacitor terminal 402.

In aspects, the first power terminal 121, the second power terminal 122, the first capacitor terminal 141, and/or the second capacitor terminal 142 may be implemented with fasteners, connectors, power connectors, connections, power connections, fastener apertures, and/or the like. In aspects, the first power module interconnect 101, the second power module interconnect 102, the first capacitor interconnect 111, and/or the second capacitor interconnect 112 may be implemented with fasteners, connectors, power connectors, connections, power connections, fastener apertures, and/or the like.

Additionally, the snubber device 100 may include a power connection 131 connecting the first power terminal 121 and the first power module interconnect 101 to the DC snubber circuit 110 and/or the at least one snubber capacitor 116. Further, the snubber device 100 may include a power connection 132 connecting the second power terminal 122 and the second power module interconnect 102 to the DC snubber circuit 110 and/or the at least one snubber capacitor 116.

Additionally, the snubber device 100 may include a power connection 151 connecting the first capacitor terminal 141 and the first capacitor interconnect 111 to the DC snubber circuit 110 and/or the at least one snubber capacitor 116. Further, the snubber device 100 may include a power connection 152 connecting the second capacitor terminal 142 and the second capacitor interconnect 112 to the DC snubber circuit 110 and/or the at least one snubber capacitor 116. In aspects, the power connection 131, the power connection 132, the power connection 151, and the power connection 152, may be implemented as busbars, wires, cables, ribbons, traces, and/or the like.

As illustrated in FIG. 3, the snubber substrate 114 may be configured to be arranged on a lower assembly surface 128 of the snubber assembly 118. In other aspects, there may be intervening structure between the snubber substrate 114 and the lower assembly surface 128. However, the intervening structure may provide thermal transfer of heat within the snubber substrate 114 to the lower assembly surface 128.

In aspects, the DC snubber circuit 110 may be configured to be arranged on an upper substrate surface 138 of the snubber substrate 114. In other aspects, there may be intervening structure between the DC snubber circuit 110 and the upper substrate surface 138. However, the intervening structure may be configured to provide thermal transfer of heat within the DC snubber circuit 110 to the snubber substrate 114. In aspects, the intervening structure may be a heat pipe as known in the art.

In aspects, the at least one snubber capacitor 116 may be configured to be arranged on the upper substrate surface 138 of the snubber substrate 114. In other aspects, there may be intervening structure between the at least one snubber capacitor 116 and the upper substrate surface 138. However, the intervening structure may be configured to provide thermal transfer of heat within the at least one snubber capacitor 116 to the snubber substrate 114. In aspects, the intervening structure may be a heat pipe as known in the art.

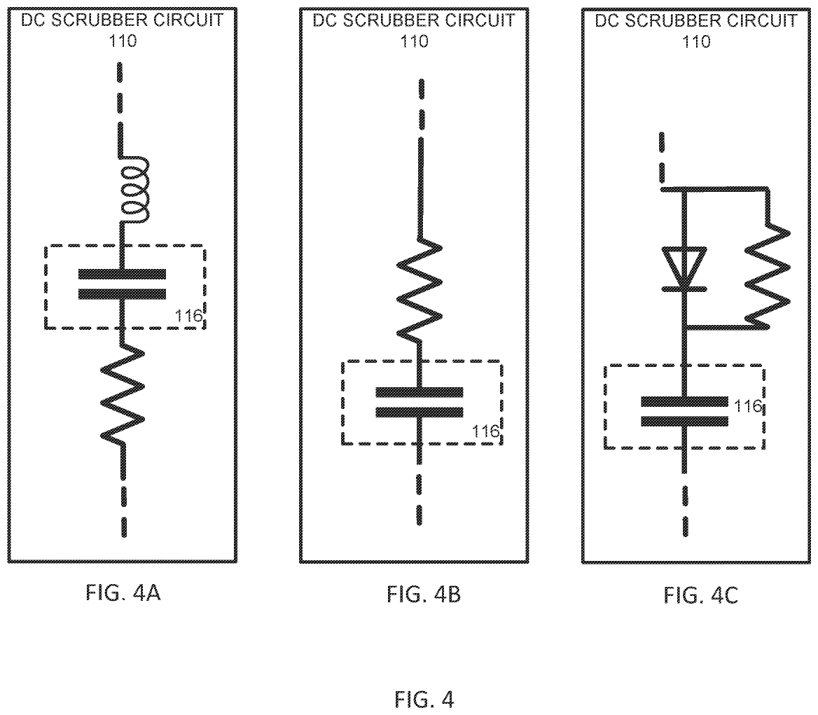

FIG. 4 includes FIG. 4A, FIG. 4B, and FIG. 4C that illustrate three exemplary schematics of the DC snubber circuit according to aspects of the disclosure.

In particular, FIG. 4 includes FIG. 4A, FIG. 4B, and FIG. 4C that illustrate three exemplary schematics of the DC snubber circuit 110 according to aspects of the disclosure. In aspects as illustrated in FIG. 4A, the DC snubber circuit 110 may include the at least one snubber capacitor 116 as described herein in series with a resistor and an inductor. However, the DC snubber circuit 110 may include additional components, fewer components, and/or other configurations.

In aspects as illustrated in FIG. 4B, the DC snubber circuit 110 may include the at least one snubber capacitor 116 as described herein in series with a resistor. However, the DC snubber circuit 110 may include additional components, fewer components, and/or other configurations.

In aspects as illustrated in FIG. 4C, the DC snubber circuit 110 may include the at least one snubber capacitor 116 as described herein in series with a diode; and the diode may be connected in parallel with a resistor. However, the DC snubber circuit 110 may include additional components, fewer components, and/or other configurations.

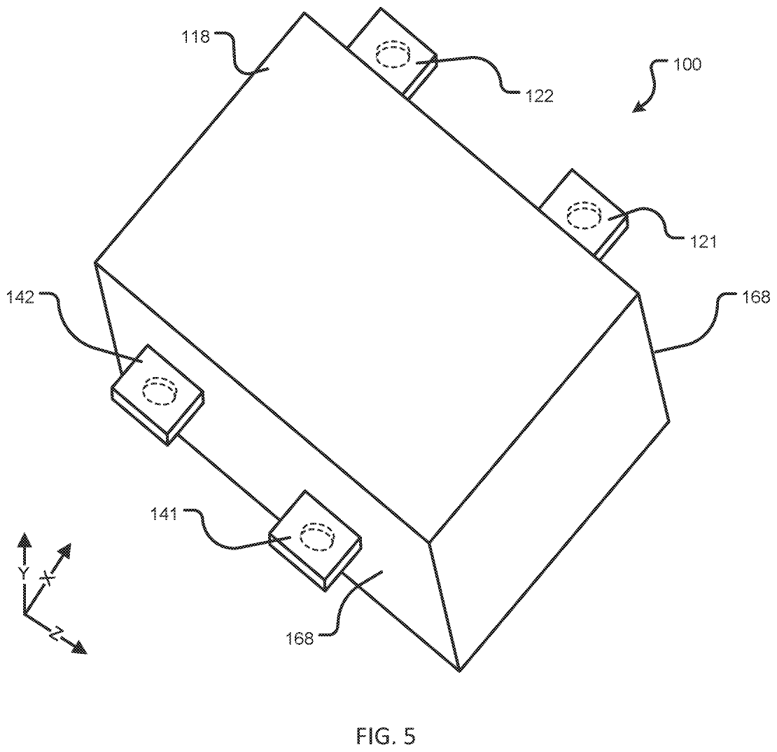

FIG. 5 illustrates a partial upper perspective view of an exemplary implementation of the snubber device according to aspects of the disclosure.

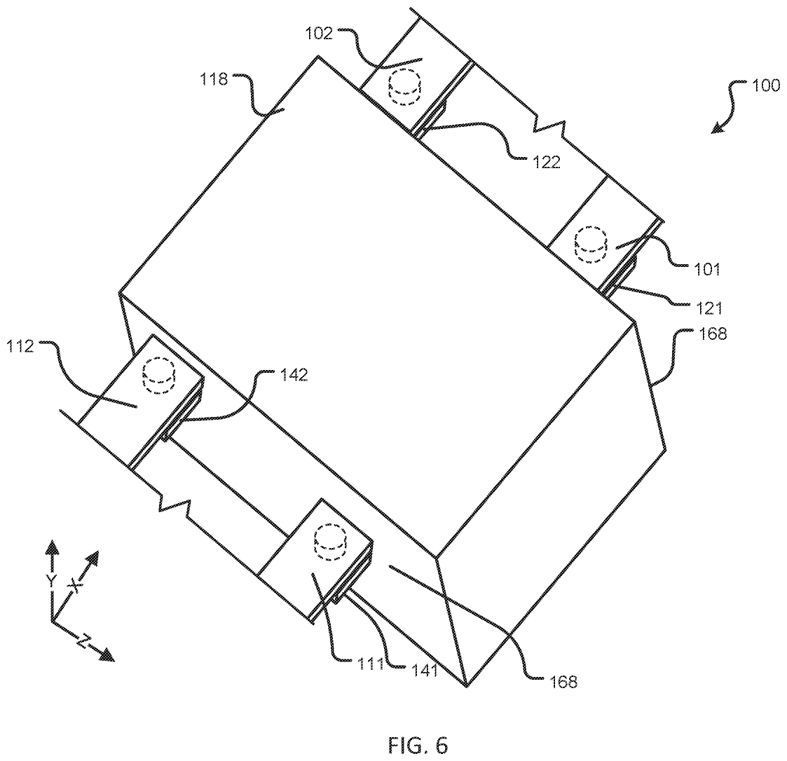

FIG. 6 illustrates a further partial upper perspective view of the exemplary implementation of the snubber device according to FIG. 5.

In particular, FIG. 5 illustrates a partial upper perspective view of an exemplary implementation of the snubber device 100 according to aspects of the disclosure. More specifically, FIG. 5 illustrates that the first capacitor terminal 141, the second capacitor terminal 142, the first power terminal 121, and the second power terminal 122 may be configured to be arranged on sides 168 of the snubber assembly 118. In this regard, the first capacitor terminal 141 and the second capacitor terminal 142 may be configured to be arranged on one of the sides 168 of the snubber assembly 118; and the first power terminal 121 and the second power terminal 122 may be configured to be arranged on another one of the sides 168 of the snubber assembly 118. In aspects, one or more of the first capacitor terminal 141, the second capacitor terminal 142, the first power terminal 121, and the second power terminal 122 may be offset vertically, may be offset horizontally, may overlap vertically, may overlap horizontally, and/or the like.

Additionally, FIG. 5 illustrates that the first capacitor terminal 141, the second capacitor terminal 142, the first power terminal 121, and/or the second power terminal 122 may be implemented with fastener apertures. However, other types of connection configurations may be implemented by the snubber device 100, the first capacitor terminal 141, the second capacitor terminal 142, the first power terminal 121, and/or the second power terminal 122. Moreover, the construction of the first capacitor terminal 141, the second capacitor terminal 142, the first power terminal 121, and the second power terminal 122 illustrated in FIG. 5 is merely exemplary. Other implementations of the first capacitor terminal 141, the second capacitor terminal 142, the first power terminal 121, and the second power terminal 122 are contemplated as disclosed herein.

FIG. 6 illustrates partial implementations of the first power module interconnect 101, the second power module interconnect 102, the first capacitor interconnect 111, and the second capacitor interconnect 112. In particular, implementations of the first power module interconnect 101, the second power module interconnect 102, the first capacitor interconnect 111, and the second capacitor interconnect 112 with the first power terminal 121, the second power terminal 122, the first capacitor terminal 141, and the second capacitor terminal 142. Additionally, FIG. 6 illustrates an exemplary fastener that may be implemented with the fastener apertures noted above and illustrated in FIG. 5. In aspects, one or more of the first power module interconnect 101, the second power module interconnect 102, the first capacitor interconnect 111, and the second capacitor interconnect 112 may be offset vertically, may be offset horizontally, may overlap vertically, may overlap horizontally, and/or the like.

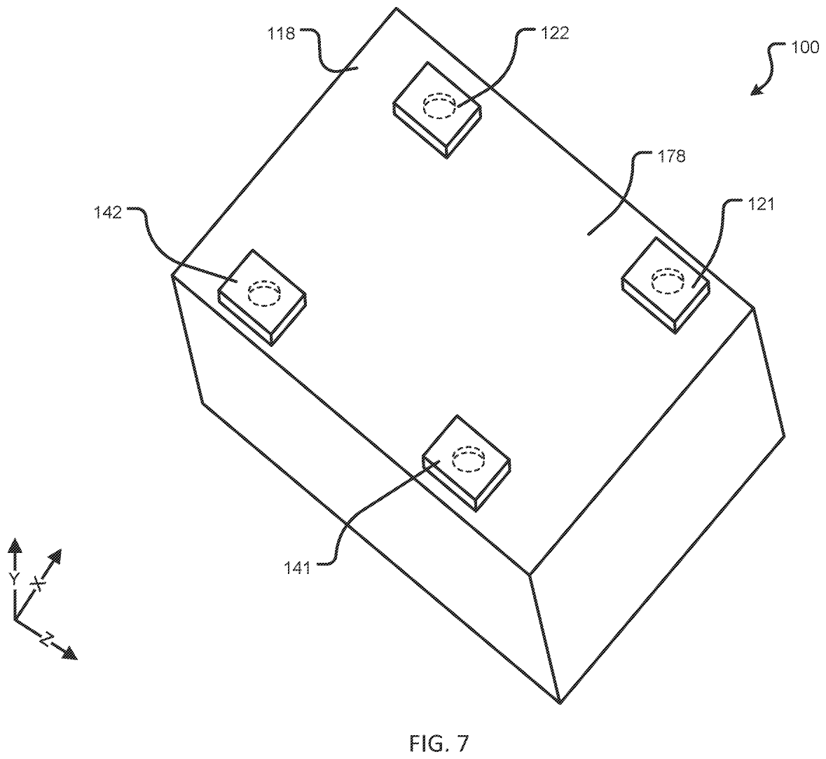

FIG. 7 illustrates a partial upper perspective view of another exemplary implementation of the snubber device according to aspects of the disclosure.

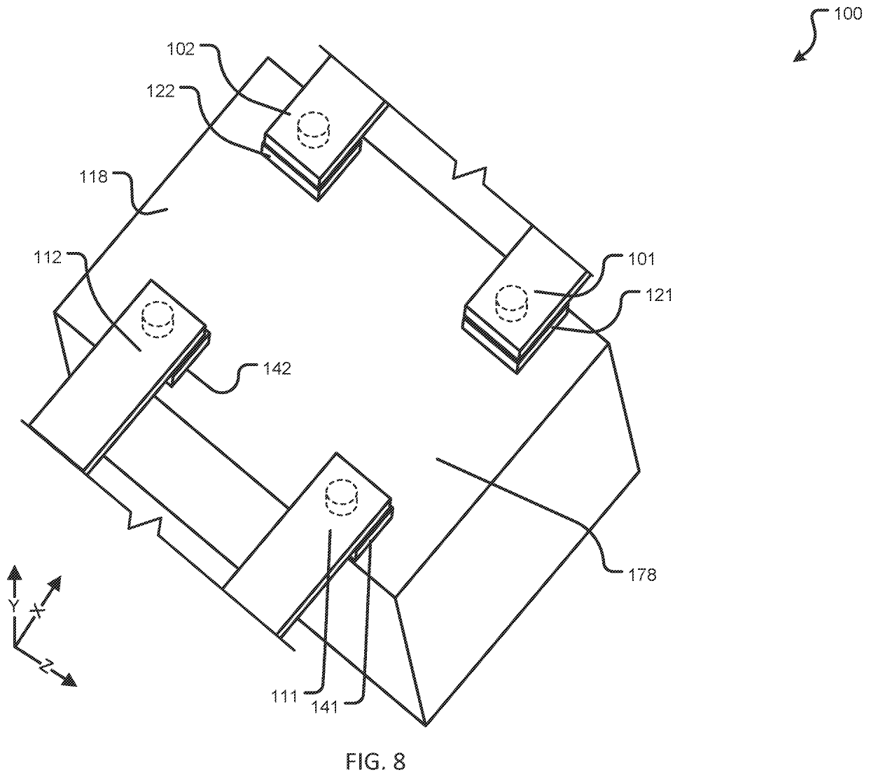

FIG. 8 illustrates a further partial upper perspective view of the another exemplary implementation of the snubber device according to FIG. 7.

In particular, FIG. 7 illustrates a partial upper perspective view of another exemplary implementation of the snubber device 100 according to aspects of the disclosure. In particular, FIG. 7 illustrates that the first capacitor terminal 141, the second capacitor terminal 142, the first power terminal 121, and the second power terminal 122 may be configured to be arranged on a top surface 178 of the snubber assembly 118. In this regard, the first capacitor terminal 141 and the second capacitor terminal 142 may be configured to be arranged on the top surface 178 of the snubber assembly 118; and the first power terminal 121 and the second power terminal 122 may also be arranged the top surface 178 of the snubber assembly 118. In aspects, one or more of the first capacitor terminal 141, the second capacitor terminal 142, the first power terminal 121, and the second power terminal 122 may be offset vertically, may be offset horizontally, may overlap vertically, may overlap horizontally, and/or the like.

Additionally, FIG. 7 illustrates that the first capacitor terminal 141, the second capacitor terminal 142, the first power terminal 121, and/or the second power terminal 122 may be implemented with fastener apertures. However, other types of connection configurations may be implemented by the snubber device 100, the first capacitor terminal 141, the second capacitor terminal 142, the first power terminal 121, and/or the second power terminal 122. Moreover, the construction of the first capacitor terminal 141, the second capacitor terminal 142, the first power terminal 121, and the second power terminal 122 illustrated in FIG. 7 is merely exemplary. Other implementations of the first capacitor terminal 141, the second capacitor terminal 142, the first power terminal 121, and the second power terminal 122 are contemplated as disclosed herein.

FIG. 8 illustrates partial implementations of the first power module interconnect 101, the second power module interconnect 102, the first capacitor interconnect 111, and the second capacitor interconnect 112. In particular, implementations of the first power module interconnect 101, the second power module interconnect 102, the first capacitor interconnect 111, and the second capacitor interconnect 112 with the first power terminal 121, the second power terminal 122, the first capacitor terminal 141, and the second capacitor terminal 142. Additionally, FIG. 8 illustrates an exemplary fastener that may be implemented with the fastener apertures noted above and illustrated in FIG. 7. In aspects, one or more of the first power module interconnect 101, the second power module interconnect 102, the first capacitor interconnect 111, and the second capacitor interconnect 112 may be offset vertically, may be offset horizontally, may overlap vertically, may overlap horizontally, and/or the like.

In further aspects not illustrated, one or more of the first capacitor terminal 141, the second capacitor terminal 142, the first power terminal 121, and the second power terminal 122 may be configured to be arranged on the top surface 178 of the snubber assembly 118; and one or more of the first capacitor terminal 141, the second capacitor terminal 142, the first power terminal 121, and the second power terminal 122 may be configured to be arranged on the sides 168 of the snubber assembly 118.

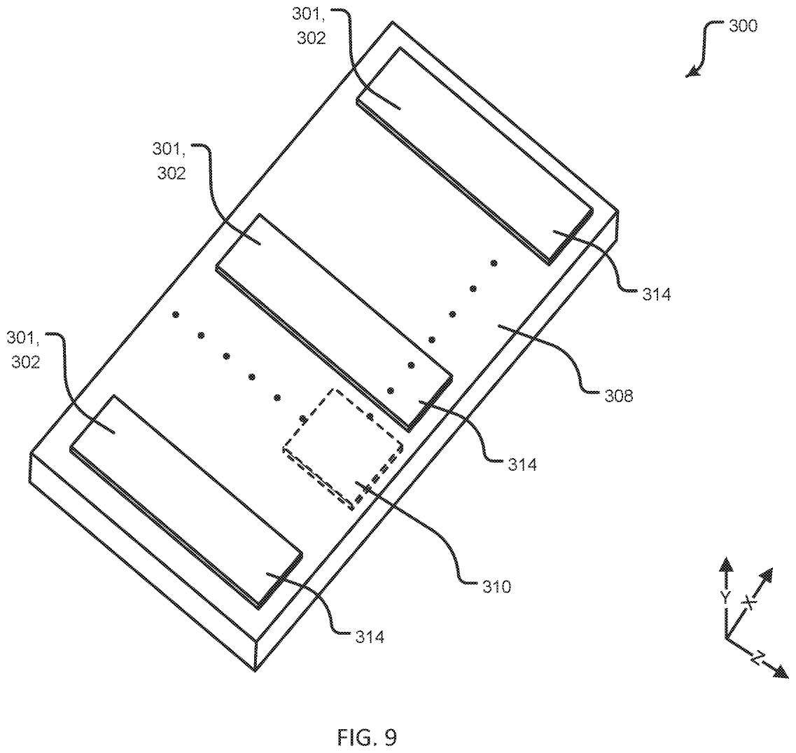

FIG. 9 illustrates an exemplary implementation of a power module according to aspects of the disclosure.

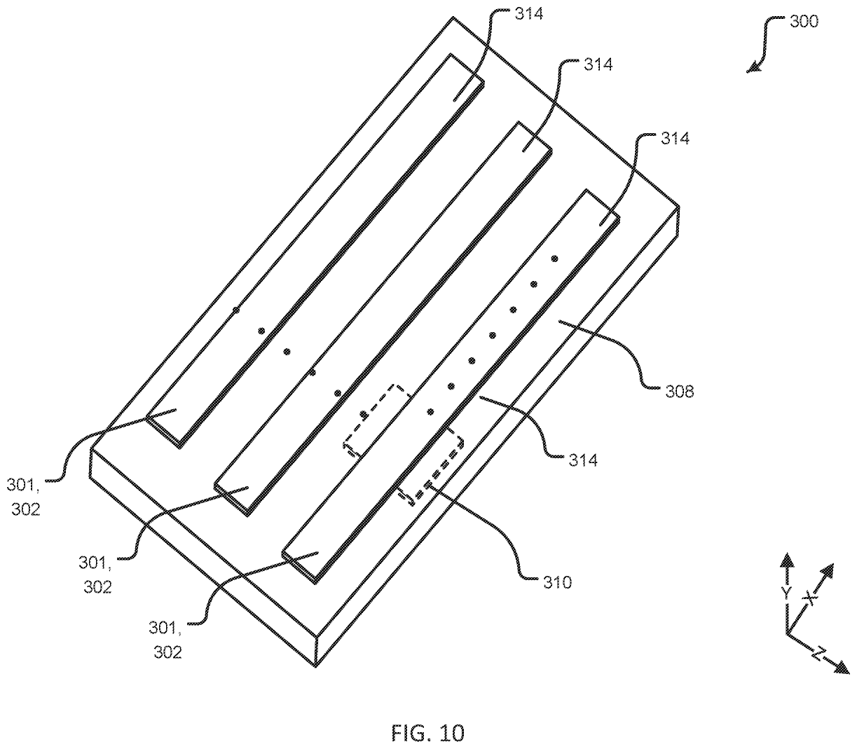

FIG. 10 illustrates another exemplary implementation of a power module according to aspects of the disclosure.

As illustrated, the power module 300 may include the power devices 310 and power contacts 314. In aspects, one of the power contacts 314 may be the first power module terminal 301; and another one of the power contacts 314 may be the second power module power terminal 302.

The power devices 310 are illustrated with dashed lines as the power devices 310 may be arranged within the power module assembly 308 of the power module 300 and accordingly may not otherwise be externally visible. Further, as noted by the dotted lines, there may be any number of the power devices 310.

In aspects, the power module 300 may be configured with and implement a plurality of the power devices 310 that may be arranged to extend along the z-axis or lateral axis. In aspects, the power module 300 may be configured with and implement a plurality of the power devices 310 that may be arranged to extend along the X-axis or longitudinal axis between the power contacts 314. In aspects, the power module 300 may be configured with and implement a plurality of the power devices 310 that may be arranged to extend along the z-axis or lateral axis; and the power module 300 may be configured with and implement a plurality of the power devices 310 that may be arranged to extend along the X-axis or longitudinal axis between the power contacts 314.

In aspects, the power contacts 314 may be structured and arranged to have at least in part a flat portion in a plane of the y-axis, the x-axis, and/or the z-axis. The flat portion of the power contacts 314 may form a contact to other components, external components, and/or the like.

Additionally, the power module assembly 308 may include an assembly top surface, assembly first sides, and assembly second sides. In aspects, the assembly first sides may be straight, inclined, irregular, curved, and/or the like. In aspects, the assembly second sides may be straight, inclined, irregular, curved, and/or the like. In aspects, the snubber device 100 may be arranged adjacent one of the assembly first sides. In aspects, the snubber device 100 may be arranged adjacent one of the assembly second sides.

In aspects of the power module 300, the power devices 310 may be arranged on the power substrate 312. In particular, the power devices 310 may be attached to the power substrate 312 by an attach, soldering, conductive epoxy, and/or the like.

The power devices 310 may be implemented as a power semiconductor device, a transistor device, a power transistor device, a diode, a power diode, a metal-oxide-semiconductor field-effect transistor (MOSFET) device, an insulated-gate bipolar transistor (IGBT) device, and/or the like. In aspects, the power devices 310 may be implemented as any type of device implementing a Silicon device, silicon carbide (SIC) device, gallium nitride (GaN) device, and/or the like. In aspects, the power devices 310 may be implemented as a power semiconductor device, a transistor device, a power transistor device, a diode, a power diode, a metal-oxide-semiconductor field-effect transistor (MOSFET) device, an insulated-gate bipolar transistor (IGBT) device that are implemented with Silicon device, silicon carbide (SiC) device, gallium nitride (GaN) device, and/or the like.

With respect to FIGS. 1-9, the snubber device 100 may be a configuration and/or structure that may be placed between the power module 300 and the at least one DC link capacitor 400. The snubber device 100 may be configured to provide a low-inductance connection between the at least one DC link capacitor 400 and the power module 300 with snubber and cooling functions via the snubber substrate 114 and/or the cold plate 304. In particular, the low inductance connection may include the first power module interconnect 101, the second power module interconnect 102, the first capacitor interconnect 111, the second capacitor interconnect 112, and/or the like.

The snubber device 100 may enable the power module 300 and/or the power system 200 to implement higher speed hard switching. Additionally, the snubber device 100 may be implemented separate from the power module 300. Accordingly, because the snubber device 100 is not part of the power module 300, the snubber device 100 may not impact qualification of the power module 300.

Further, the snubber device 100 may be implemented separate from the at least one DC link capacitor 400, the application 500, other components of the power system 200, and/or the like to provide improved cooling of the snubber device 100. In particular, improved cooling through implementation of the snubber substrate 114 and/or the cold plate 304.

In aspects, implementation of the snubber device 100 may provide damping within the power system 200 that may include the power module 300, the at least one DC link capacitor 400, the application 500, and/or the like. In particular, the snubber device 100 may be configured with the DC snubber circuit 110 and/or the at least one snubber capacitor 116 to provide damping within the power system 200 that may include the power module 300, the at least one DC link capacitor 400, the application 500, and/or the like.

In aspects, implementation of the snubber device 100 may be configured with cooling through the snubber substrate 114. In aspects, implementation of the snubber device 100 may be configured with cooling through the snubber substrate 114 and/or the cold plate 304. In particular, a portion of the cold plate 304 separate from the power module 300.

In particular, implementation of the snubber device 100 may be configured with cooling of the DC snubber circuit 110 and/or the at least one snubber capacitor 116 through the snubber substrate 114 that is implemented separate from the power module 300. In aspects, implementation of the snubber device 100 may be configured with cooling of the DC snubber circuit 110 and/or the at least one snubber capacitor 116 through the snubber substrate 114 and/or the cold plate 304.

In aspects, implementation of the snubber device 100 may allow the power module 300, the at least one DC link capacitor 400, the application 500, and/or the power system 200 to implement high ripple current capability. In this regard, the power system 200 may implement the snubber device 100 between the at least one DC link capacitor 400 and the power module 300. Further, the snubber device 100 may be implemented separate from the power module 300. Accordingly, the snubber device 100 may not affect conventional qualification procedures of the power module 300.

Further, the snubber device 100 may be configured with the first power module interconnect 101 and the second power module interconnect 102 implementing a low-inductive bus bar interconnection to the power module 300. In aspects, the snubber device 100 may be configured with the first power module interconnect 101 implementing a low-inductive bus bar interconnection to the first power module terminal 301 of the power module 300. In aspects, the snubber device 100 may be configured with the second power module interconnect 102 implementing a low-inductive bus bar interconnection to the second power module power terminal 302 of the power module 300.

In aspects, the first power module interconnect 101 and the second power module interconnect 102 may be optimized for certain implementations of the power module 300. In aspects, the first power module interconnect 101 and the second power module interconnect 102 may be optimized for certain implementations of the first power module terminal 301 and the second power module power terminal 302 of the power module 300.

In aspects, the first power module interconnect 101 and the second power module interconnect 102 may be configured as low-inductive bus bar interconnections that may be optimized for certain implementations of the power module 300. In aspects, the first power module interconnect 101 and the second power module interconnect 102 may be configured as low-inductive bus bar interconnections that may be optimized for certain implementations of the first power module terminal 301 and the second power module power terminal 302 of the power module 300.

Moreover, the snubber device 100 and/or the DC snubber circuit 110 may be configured considering the interconnection to the at least one DC link capacitor 400. In aspects, the snubber device 100 and/or the DC snubber circuit 110 may be configured with the first capacitor interconnect 111 and the second capacitor interconnect 112 considering the interconnection to the at least one DC link capacitor 400.

In aspects, the snubber device 100 may be configured to be well cooled. In particular, the snubber device 100 may be configured to be well cooled with a configuration and arrangement of the snubber substrate 114. More specifically, the snubber device 100 may be configured to be well cooled with a configuration and arrangement of the DC snubber circuit 110 and/or the at least one snubber capacitor 116 in thermal communication with the snubber substrate 114 and/or the cold plate 304.

Further, the snubber device 100 may implement the at least one snubber capacitor 116 with a higher ESR may substantially damp oscillations within the power module 300, the at least one DC link capacitor 400, the application 500, and/or the power system 200. In this regard, energy from oscillations may heat up the snubber device 100, the DC snubber circuit 110, the at least one snubber capacitor 116, and/or the like. Therefore, the snubber device 100 may be cooled, such as through the snubber substrate 114 and/or the cold plate 304.

In aspects, a capacitance value implemented by the at least one snubber capacitor 116 of the snubber device 100 and/or the DC snubber circuit 110 may be much lower than a capacitance of the at least one DC link capacitor 400. Accordingly, the snubber device 100 may be geometrically smaller. Accordingly, the snubber device 100 may be placed and/or arranged low-inductively close to the power module 300. Additionally, the snubber device 100 may be configured to be arranged on the cold plate 304 beside the power module 300.

In aspects, implementation of the snubber device 100 in the power system 200 prevents the need to reduce an internal ohmic resistance, also called equivalent series resistance (ESR), of the at least one DC link capacitor 400. Accordingly, a switching moment of oscillation may be damped and prevent and/or substantially reduce significant oscillations between the power module 300 and the at least one DC link capacitor 400. Additionally, implementation of the snubber device 100 in the power system 200 may prevent and/or reduce electromagnetic interference issues within the power system 200, the power module 300, the at least one DC link capacitor 400, the application 500, and/or the like.

As disclosed, the snubber device 100 may be configured to be arranged separate from the power module 300. In this regard, placing the snubber device 100 in the power module 300 would significantly complicate qualification of the power module 300. A further disadvantage is that the low-inductive low-ESR LCV DC link capacitors may cause high di/dt (rate of current change) in a short-circuit case. Moreover, the snubber device 100 may be configured to be arranged separate from the power module 300 to provide improved cooling of the snubber device 100, the DC snubber circuit 110, the at least one snubber capacitor 116, and/or the like.

In aspects, the disclosed implementation of the snubber device 100 including the DC snubber circuit 110, the at least one snubber capacitor 116, the snubber substrate 114, the cold plate 304, and/or the like may be configured to provide proper current damping, good cooling, low-inductive interconnection to the power module 300, high ripple current capability, and/or the like.

In aspects, the disclosed implementation of the snubber device 100 including the DC snubber circuit 110, the at least one snubber capacitor 116, the snubber substrate 114, the cold plate 304, and/or the like may be arranged separately and between a large capacitance implementation of the at least one DC link capacitor 400 and the power module 300. This configuration may provide a number of potential benefits.

In aspects, the potential benefits may include little or no impact to conventional qualification procedures of the power module 300; the snubber device 100 may implement a low-inductive bus bar interconnection to the power module 300, which may be optimized for certain implementations of the power module 300; the snubber device 100 may contain inside the DC snubber circuit 110 and the at least one snubber capacitor 116. For example, an implementation of the at least one snubber capacitor 116 having a capacitor with higher ESR than a typical MLCC, RC circuit, RCD circuit. Further, the snubber device 100 and/or the DC snubber circuit 110 may be configured in consideration of the interconnection to the at least one DC link capacitor 400; and the snubber device 100 may be well cooled through implementation of the snubber substrate 114 and/or the cold plate 304.

In this regard, the higher ESR capacitor implementation of the at least one snubber capacitor 116 may substantially damp the oscillations. The energy from the oscillations may heat up the snubber device 100 and/or the DC snubber circuit 110. Therefore, the snubber device 100 and/or the DC snubber circuit 110 may be cooled via the snubber substrate 114 and/or the cold plate 304. Due to the fact that the capacitance value used in the snubber device 100 and/or the DC snubber circuit 110 may be much lower than in the at least one DC link capacitor 400, the snubber device 100 and/or the DC snubber circuit 110 may be geometrically small and may be placed in a number of different arrangements. For example, the snubber device 100 and/or the DC snubber circuit 110 may be configured to be arranged: (a) low-inductively close to the power module; and/or (b) on the cold plate 304 beside the power module.

For high voltage applications, such as applications greater than 60 V, the snubber device 100 and/or the DC snubber circuit 110 may be isolated from the snubber substrate 114 and/or the cold plate 304 providing safety insulation. For this purpose, the DC snubber circuit 110 may be placed on a high thermally conductive, but electrically isolating substrate implemented as the snubber substrate 114. For example, the substrate may be an active metal braze (AMB) substrate, a direct bond copper (DBC) substrate, an insulated metal substrate (IMS), a direct copper bonded (DCB) substrate, a direct printed copper (DPC) substrate, and/or the like.

In aspects, the disclosure relates to placement of the snubber device 100 outside of the power module 300 in combination with a low-inductive connection to the power module 300 and enhanced cooling via the snubber substrate 114 and/or the cold plate 304. For example, the enhanced cooling may include a highly thermally conductive isolating substrate. Accordingly, the snubber device 100 may allow for: reduction of switching losses; fast and nearly oscillation-free switching; greater flexibility of interconnection to the at least one DC link capacitor 400; shift some losses from the at least one DC link capacitor 400, which may be hard to cool, to well cooled configuration of the snubber device 100. In this regard, keeping the at least one DC link capacitor 400 cool may be critical for its lifetime/failure rate and electrical performance; usage of cheaper conventional LCV DC link capacitors with lower ripple current requirements. As this requirement leads usually to higher required capacitance value of the LCV DC link capacitors, then possibly to reduction of the minimal required capacitance value of RCV DC link capacitor; shift some switching energy from the power devices 310 to the snubber device 100 and therefore give additional thermal headroom for the power devices 310; thermo-mechanical decoupling from the power module 300 and potentially higher system reliability; and/or the like.

Accordingly, the disclosed device may reduce the cost of a switching cell system that includes a RCV DC link capacitor, DC link-snubber circuit, a power module, and/or the like.

In one aspect, the snubber device 100 includes the snubber assembly 118. The snubber device 100 in addition includes the DC snubber circuit 110 having the at least one snubber capacitor 116. The device moreover includes the snubber substrate 114. The device also includes where the snubber device 100 is configured to be arranged outside and separate from the power module 300.

The application 500 may be an application with high-power hard switching such as a traction inverter, a solar inverter, and/or the like. Additionally, other fast switching systems may also benefit from implementations of the disclosed device. In aspects, the application 500 may be a power system, a motor system, a motor drive, an automotive motor system, a charging system, an automotive charging system, a vehicle system, an industrial motor drive, an embedded motor drive, an uninterruptible power supply, an AC-DC power supply, a welder power supply, a military system, an inverter, an inverter for wind turbines, solar power panels, tidal power plants, electric vehicles (EVs), a converter, a circuit breaker, a protection circuit, a DC-DC converter, an Off-Board DC Fast Charger for an electric vehicle (EV), an on-board DC/DC Converter for an electric vehicle (EV), an on-board battery charger for an electric vehicle (EV), an electric vehicle (EV) Powertrain/Main Inverter, an electric vehicle (EV) charging infrastructure, an electric traction motor, a motor drive for an electric motor, a commercial inductive heating system, an uninterruptible power system, a power system, a motor system, a motor drive, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, solar inverters, circuit breakers, protection circuits, DC-DC converters, Off-Board DC Fast Chargers for electric vehicles (EVs) and the like, on-board DC/DC Converters for electric vehicles (EVs) and the like, on-board battery chargers for electric vehicles (EVs) and the like, electric vehicle (EV) Powertrains/Main Inverters, electric vehicle (EV) charging infrastructures, electric traction motors, motor drives for electric motors, commercial inductive heating systems, uninterruptible power systems, and/or the like.

Accordingly, the disclosure has set forth a device and process to increase switching speed in power modules, reduce switching losses in power modules, and/or the like.

The following are a number of nonlimiting EXAMPLES of aspects of the disclosure.

One EXAMPLE: a snubber device includes a snubber assembly. The snubber device in addition includes a snubber circuit comprising at least one snubber capacitor. The snubber device moreover includes a snubber substrate. The snubber device also includes where the snubber assembly is configured to be arranged outside and separate from the power module.

The above-noted EXAMPLE may further include any one or a combination of more than one of the following EXAMPLES: The snubber device of the above-noted EXAMPLE where the snubber device is configured to be arranged in the snubber assembly separate from the power module and/or a power module assembly. The snubber device of the above-noted EXAMPLE where at least the snubber circuit is configured to be arranged in the snubber assembly separate from the power module and/or a power module assembly. The snubber device of the above-noted EXAMPLE where at least the at least one snubber capacitor is configured to be arranged in the snubber assembly separate from the power module and/or a power module assembly. The snubber device of the above-noted EXAMPLE where at least the at least one snubber capacitor is configured to be arranged outside and separate from a power module assembly. The snubber device of the above-noted EXAMPLE where at least the snubber circuit is configured to be arranged outside and separate from a power module assembly. The snubber device of the above-noted EXAMPLE where at least the snubber substrate is at least partially configured and arranged within the snubber assembly. The snubber device of the above-noted EXAMPLE where the at least one snubber capacitor is configured and arranged within the snubber assembly. The snubber device of the above-noted EXAMPLE where the snubber circuit is configured and arranged within the snubber assembly. The snubber device of the above-noted EXAMPLE where the power module comprises a power module assembly; and where the snubber device is configured to be arranged outside and separate from the power module assembly. The snubber device of the above-noted EXAMPLE where the snubber substrate is configured as a heat sink. The snubber device of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The snubber device of the above-noted EXAMPLE where the snubber assembly is a housing. The snubber device of the above-noted EXAMPLE where the snubber circuit is configured to be in thermal communication with the snubber substrate. The snubber device of the above-noted EXAMPLE where the at least one snubber capacitor is configured to be in thermal communication with the snubber substrate. The snubber device of the above-noted EXAMPLE where the at least one snubber capacitor is configured such that heat within the at least one snubber capacitor is transferred to the snubber substrate. The snubber device of the above-noted EXAMPLE where the snubber device is configured to be arranged on a portion of a cold plate. The snubber device of the above-noted EXAMPLE where the power module is configured to be arranged on a portion of the cold plate. The snubber device of the above-noted EXAMPLE where the snubber device is configured such that heat within the snubber circuit is transferred to the snubber substrate and then to the cold plate. The snubber device of the above-noted EXAMPLE where the snubber circuit is configured such that heat within the snubber circuit is transferred to the cold plate. The snubber device of the above-noted EXAMPLE where the at least one snubber capacitor configured such that heat within the at least one snubber capacitor is transferred to the cold plate. The snubber device of the above-noted EXAMPLE where the at least one snubber capacitor is configured such that heat within the at least one snubber capacitor is transferred to the snubber substrate and then to the cold plate. The snubber device of the above-noted EXAMPLE where the snubber device is configured to connect to and/or further comprises power module interconnects configured to connect the snubber device to the power module. The snubber device of the above-noted EXAMPLE where the power module interconnects are structured and configured to have lower inductance; and where the snubber circuit is configured to allow increased switching speeds for the power module. The snubber device of the above-noted EXAMPLE where the power module interconnects are configured to connect the snubber device to power terminals of the power module. The snubber device of the above-noted EXAMPLE where the snubber device is configured to connect to and/or further comprises a first power module interconnect and a second power module interconnect. The snubber device of the above-noted EXAMPLE where the first power module interconnect is configured to connect the snubber device to a first power module terminal of the power module; and where the second power module interconnect is configured to connect to a second power module power terminal of the power module. The snubber device of the above-noted EXAMPLE where the first power module interconnect and the second power module interconnect are configured to connect to the snubber circuit. The snubber device of the above-noted EXAMPLE where the first power module interconnect and/or the second power module interconnect are implemented as busbars, wires, cables, and/or ribbons. The snubber device of the above-noted EXAMPLE where the first power module interconnect and/or the second power module interconnect comprise buss bars. The snubber device of the above-noted EXAMPLE includes at least a first power terminal and a second power terminal. The snubber device of the above-noted EXAMPLE where the first power terminal is configured to connect to the first power module interconnect; and where the second power terminal is configured to connect to the second power module interconnect. The snubber device of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The snubber device of the above-noted EXAMPLE where the snubber device is configured to connect to and/or comprises capacitor interconnects that are configured to connect the snubber device to the at least one DC link capacitor. The snubber device of the above-noted EXAMPLE where the capacitor interconnects are structured and configured to have lower inductance; and where the snubber circuit is configured to allow increased switching speeds for the power module. The snubber device of the above-noted EXAMPLE where the snubber device is configured to connect to and/or comprises a first capacitor interconnect and a second capacitor interconnect. The snubber device of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The snubber device of the above-noted EXAMPLE where the first capacitor interconnect and/or the second capacitor interconnect, are implemented as busbars, wires, cables, and/or ribbons. The snubber device of the above-noted EXAMPLE where the first capacitor interconnect and the second capacitor interconnect are configured to connect to the snubber circuit. The snubber device of the above-noted EXAMPLE where the first capacitor interconnect and/or the second capacitor interconnect comprise buss bars. The snubber device of the above-noted EXAMPLE includes a first capacitor terminal and a second capacitor terminal. The snubber device of the above-noted EXAMPLE where the first capacitor terminal is configured to connect the snubber device to the first capacitor interconnect; and where the second capacitor terminal is configured to connect the snubber device to the second capacitor interconnect. The snubber device of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The snubber device of the above-noted EXAMPLE where the snubber circuit is configured to allow increased switching speeds for the power module. The snubber device of the above-noted EXAMPLE where the snubber substrate is configured to be arranged on a lower assembly surface of the snubber assembly. The snubber device of the above-noted EXAMPLE where the snubber circuit is configured to be arranged on an upper substrate surface of the snubber substrate. The snubber device of the above-noted EXAMPLE where the at least one snubber capacitor is configured to be arranged on an upper substrate surface of the snubber substrate. The snubber device of the above-noted EXAMPLE where the snubber circuit further comprises a resistor. The snubber device of the above-noted EXAMPLE where the snubber circuit further comprises a diode. The snubber device of the above-noted EXAMPLE where the snubber circuit further comprises a resistor and a diode. The snubber device of the above-noted EXAMPLE where the power system is configured to provide power to an application.

One EXAMPLE: a snubber device includes a snubber assembly. The snubber device in addition includes a snubber circuit comprising at least one snubber capacitor. The snubber device moreover includes a snubber substrate. The snubber device also includes where the snubber device is configured to connect to power module interconnects that connect the snubber device to the power module. The snubber device further includes where the snubber device is configured to connect to capacitor interconnects that connect the snubber device to the at least one DC link capacitor.

The above-noted EXAMPLE may further include any one or a combination of more than one of the following EXAMPLES: The snubber device of the above-noted EXAMPLE where at least the snubber circuit is configured to be arranged outside and separate from the power module. The snubber device of the above-noted EXAMPLE where at least the at least one snubber capacitor is configured to be arranged outside and separate from the power module. The snubber device of the above-noted EXAMPLE where the snubber device is configured to be arranged outside and separate from the power module. The snubber device of the above-noted EXAMPLE where the snubber device is configured to be arranged in the snubber assembly separate from the power module and/or a power module assembly. The snubber device of the above-noted EXAMPLE where at least the snubber circuit is configured to be arranged in the snubber assembly separate from the power module and/or a power module assembly. The snubber device of the above-noted EXAMPLE where at least the at least one snubber capacitor is configured to be arranged in the snubber assembly separate from the power module and/or a power module assembly. The snubber device of the above-noted EXAMPLE where at least the at least one snubber capacitor is configured to be arranged outside and separate from a power module assembly. The snubber device of the above-noted EXAMPLE where at least the snubber circuit is configured to be arranged outside and separate from a power module assembly. The snubber device of the above-noted EXAMPLE where at least the snubber substrate is at least partially configured and arranged within the snubber assembly. The snubber device of the above-noted EXAMPLE where the at least one snubber capacitor is configured and arranged within the snubber assembly. The snubber device of the above-noted EXAMPLE where the snubber circuit is configured and arranged within the snubber assembly. The snubber device of the above-noted EXAMPLE where the power module comprises a power module assembly; and where the snubber device is configured to be arranged outside and separate from the power module assembly. The snubber device of the above-noted EXAMPLE where the snubber substrate is configured as a heat sink. The snubber device of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The snubber device of the above-noted EXAMPLE where the snubber assembly is a housing. The snubber device of the above-noted EXAMPLE where the snubber circuit is configured to be in thermal communication with the snubber substrate. The snubber device of the above-noted EXAMPLE where the at least one snubber capacitor is configured to be in thermal communication with the snubber substrate. The snubber device of the above-noted EXAMPLE where the at least one snubber capacitor is configured such that heat within the at least one snubber capacitor is transferred to the snubber substrate. The snubber device of the above-noted EXAMPLE where the snubber device is configured to be arranged on a portion of a cold plate. The snubber device of the above-noted EXAMPLE where the power module is configured to be arranged on a portion of the cold plate. The snubber device of the above-noted EXAMPLE where the snubber device is configured such that heat within the snubber circuit is transferred to the snubber substrate and then to the cold plate. The snubber device of the above-noted EXAMPLE where the snubber circuit is configured such that heat within the snubber circuit is transferred to the cold plate. The snubber device of the above-noted EXAMPLE where the at least one snubber capacitor configured such that heat within the at least one snubber capacitor is transferred to the cold plate. The snubber device of the above-noted EXAMPLE where the at least one snubber capacitor is configured such that heat within the at least one snubber capacitor is transferred to the snubber substrate and then to the cold plate. The snubber device of the above-noted EXAMPLE where the snubber device comprises the power module interconnects configured to connect the snubber device to the power module. The snubber device of the above-noted EXAMPLE where the power module interconnects are configured to connect the snubber device to power terminals of the power module. The snubber device of the above-noted EXAMPLE where the power module interconnects are structured and configured to have lower inductance; and where the snubber circuit is configured to allow increased switching speeds for the power module. The snubber device of the above-noted EXAMPLE where the snubber device is configured to connect to and/or further comprises a first power module interconnect and a second power module interconnect. The snubber device of the above-noted EXAMPLE where the first power module interconnect is configured to connect the snubber device to a first power module terminal of the power module; and where the second power module interconnect is configured to connect to a second power module power terminal of the power module. The snubber device of the above-noted EXAMPLE where the first power module interconnect and the second power module interconnect are configured to connect to the snubber circuit. The snubber device of the above-noted EXAMPLE where the first power module interconnect and/or the second power module interconnect are implemented as busbars, wires, cables, and/or ribbons. The snubber device of the above-noted EXAMPLE where the first power module interconnect and/or the second power module interconnect comprise buss bars. The snubber device of the above-noted EXAMPLE includes at least a first power terminal and a second power terminal. The snubber device of the above-noted EXAMPLE where the first power terminal is configured to connect to the first power module interconnect; and where the second power terminal is configured to connect to the second power module interconnect. The snubber device of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The snubber device of the above-noted EXAMPLE where the snubber device comprises the capacitor interconnects that are configured to connect the snubber device to the at least one DC link capacitor. The snubber device of the above-noted EXAMPLE where the capacitor interconnects are structured and configured to have lower inductance; and where the snubber circuit is configured to allow increased switching speeds for the power module. The snubber device of the above-noted EXAMPLE where the snubber device is configured to connect to and/or comprises a first capacitor interconnect and a second capacitor interconnect. The snubber device of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The snubber device of the above-noted EXAMPLE where the first capacitor interconnect and/or the second capacitor interconnect, are implemented as busbars, wires, cables, and/or ribbons. The snubber device of the above-noted EXAMPLE where the first capacitor interconnect and the second capacitor interconnect are configured to connect to the snubber circuit. The snubber device of the above-noted EXAMPLE where the first capacitor interconnect and/or the second capacitor interconnect comprise buss bars. The snubber device of the above-noted EXAMPLE includes a first capacitor terminal and a second capacitor terminal. The snubber device of the above-noted EXAMPLE where the first capacitor terminal is configured to connect the snubber device to the first capacitor interconnect; and where the second capacitor terminal is configured to connect the snubber device to the second capacitor interconnect. The snubber device of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The snubber device of the above-noted EXAMPLE where the snubber substrate is configured to be arranged on a lower assembly surface of the snubber assembly. The snubber device of the above-noted EXAMPLE where the snubber circuit is configured to allow increased switching speeds for the power module. The snubber device of the above-noted EXAMPLE where the snubber circuit is configured to be arranged on an upper substrate surface of the snubber substrate. The snubber device of the above-noted EXAMPLE where the at least one snubber capacitor is configured to be arranged on an upper substrate surface of the snubber substrate. The snubber device of the above-noted EXAMPLE where the snubber circuit further comprises a resistor. The snubber device of the above-noted EXAMPLE where the snubber circuit further comprises a diode. The snubber device of the above-noted EXAMPLE where the snubber circuit further comprises a resistor and a diode. The snubber device of the above-noted EXAMPLE where the power system is configured to provide power to an application.

One EXAMPLE: a snubber device includes a snubber assembly. The snubber device in addition includes a snubber circuit comprising at least one snubber capacitor. The snubber device moreover includes a snubber substrate. The snubber device also includes where at least the at least one snubber capacitor is configured to be arranged outside and separate from the power module.

The above-noted EXAMPLE may further include any one or a combination of more than one of the following EXAMPLES: The snubber device of the above-noted EXAMPLE where the snubber device is configured to be arranged outside and separate from the power module. The snubber device of the above-noted EXAMPLE where at least the snubber circuit is configured to be arranged outside and separate from the power module. The snubber device of the above-noted EXAMPLE where the snubber device is configured to be arranged in the snubber assembly separate from the power module and/or a power module assembly. The snubber device of the above-noted EXAMPLE where at least the snubber circuit is configured to be arranged in the snubber assembly separate from the power module and/or a power module assembly. The snubber device of the above-noted EXAMPLE where at least the at least one snubber capacitor is configured to be arranged in the snubber assembly separate from the power module and/or a power module assembly. The snubber device of the above-noted EXAMPLE where at least the at least one snubber capacitor is configured to be arranged outside and separate from a power module assembly. The snubber device of the above-noted EXAMPLE where at least the snubber circuit is configured to be arranged outside and separate from a power module assembly. The snubber device of the above-noted EXAMPLE where at least the snubber substrate is at least partially configured and arranged within the snubber assembly. The snubber device of the above-noted EXAMPLE where the at least one snubber capacitor is configured and arranged within the snubber assembly. The snubber device of the above-noted EXAMPLE where the snubber circuit is configured and arranged within the snubber assembly. The snubber device of the above-noted EXAMPLE where the power module comprises a power module assembly; and where the snubber device is configured to be arranged outside and separate from the power module assembly. The snubber device of the above-noted EXAMPLE where the snubber substrate is configured as a heat sink. The snubber device of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The snubber device of the above-noted EXAMPLE where the snubber assembly is a housing. The snubber device of the above-noted EXAMPLE where the snubber circuit is configured to be in thermal communication with the snubber substrate. The snubber device of the above-noted EXAMPLE where the at least one snubber capacitor is configured to be in thermal communication with the snubber substrate. The snubber device of the above-noted EXAMPLE where the at least one snubber capacitor is configured such that heat within the at least one snubber capacitor is transferred to the snubber substrate. The snubber device of the above-noted EXAMPLE where the snubber device is configured to be arranged on a portion of a cold plate. The snubber device of the above-noted EXAMPLE where the power module is configured to be arranged on a portion of the cold plate. The snubber device of the above-noted EXAMPLE where the snubber device is configured such that heat within the snubber circuit is transferred to the snubber substrate and then to the cold plate. The snubber device of the above-noted EXAMPLE where the snubber circuit is configured such that heat within the snubber circuit is transferred to the cold plate. The snubber device of the above-noted EXAMPLE where the at least one snubber capacitor configured such that heat within the at least one snubber capacitor is transferred to the cold plate. The snubber device of the above-noted EXAMPLE where the at least one snubber capacitor is configured such that heat within the at least one snubber capacitor is transferred to the snubber substrate and then to the cold plate. The snubber device of the above-noted EXAMPLE where the snubber device is configured to connect to and/or further comprises power module interconnects configured to connect the snubber device to the power module. The snubber device of the above-noted EXAMPLE where the power module interconnects are structured and configured to have lower inductance; and where the snubber circuit is configured to allow increased switching speeds for the power module. The snubber device of the above-noted EXAMPLE where the power module interconnects are configured to connect the snubber device to power terminals of the power module. The snubber device of the above-noted EXAMPLE where the snubber device is configured to connect to and/or further comprises a first power module interconnect and a second power module interconnect. The snubber device of the above-noted EXAMPLE where the first power module interconnect is configured to connect the snubber device to a first power module terminal of the power module; and where the second power module interconnect is configured to connect to a second power module power terminal of the power module. The snubber device of the above-noted EXAMPLE where the first power module interconnect and the second power module interconnect are configured to connect to the snubber circuit. The snubber device of the above-noted EXAMPLE where the first power module interconnect and/or the second power module interconnect are implemented as busbars, wires, cables, and/or ribbons. The snubber device of the above-noted EXAMPLE where the first power module interconnect and/or the second power module interconnect comprise buss bars. The snubber device of the above-noted EXAMPLE includes at least a first power terminal and a second power terminal. The snubber device of the above-noted EXAMPLE where the first power terminal is configured to connect to the first power module interconnect; and where the second power terminal is configured to connect to the second power module interconnect. The snubber device of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The snubber device of the above-noted EXAMPLE where the snubber device is configured to connect to and/or comprises capacitor interconnects that are configured to connect the snubber device to the at least one DC link capacitor. The snubber device of the above-noted EXAMPLE where the capacitor interconnects are structured and configured to have lower inductance; and where the snubber circuit is configured to allow increased switching speeds for the power module. The snubber device of the above-noted EXAMPLE where the snubber device is configured to connect to and/or comprises a first capacitor interconnect and a second capacitor interconnect. The snubber device of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The snubber device of the above-noted EXAMPLE where the first capacitor interconnect and/or the second capacitor interconnect, are implemented as busbars, wires, cables, and/or ribbons. The snubber device of the above-noted EXAMPLE where the first capacitor interconnect and the second capacitor interconnect are configured to connect to the snubber circuit. The snubber device of the above-noted EXAMPLE where the first capacitor interconnect and/or the second capacitor interconnect comprise buss bars. The snubber device of the above-noted EXAMPLE includes a first capacitor terminal and a second capacitor terminal. The snubber device of the above-noted EXAMPLE where the first capacitor terminal is configured to connect the snubber device to the first capacitor interconnect; and where the second capacitor terminal is configured to connect the snubber device to the second capacitor interconnect. The snubber device of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The snubber device of the above-noted EXAMPLE where the snubber substrate is configured to be arranged on a lower assembly surface of the snubber assembly. The snubber device of the above-noted EXAMPLE where the snubber circuit is configured to allow increased switching speeds for the power module. The snubber device of the above-noted EXAMPLE where the snubber circuit is configured to be arranged on an upper substrate surface of the snubber substrate. The snubber device of the above-noted EXAMPLE where the at least one snubber capacitor is configured to be arranged on an upper substrate surface of the snubber substrate. The snubber device of the above-noted EXAMPLE where the snubber circuit further comprises a resistor. The snubber device of the above-noted EXAMPLE where the snubber circuit further comprises a diode. The snubber device of the above-noted EXAMPLE where the snubber circuit further comprises a resistor and a diode. The snubber device of the above-noted EXAMPLE where the power system is configured to provide power to an application.

One EXAMPLE: a process includes providing a snubber assembly. The process in addition includes providing a snubber circuit comprising at least one snubber capacitor. The process moreover includes providing a snubber substrate. The process also includes configuring and arranging the snubber assembly outside and separate from the power module.

The above-noted EXAMPLE may further include any one or a combination of more than one of the following EXAMPLES: The process of the above-noted EXAMPLE includes configuring and arranging the snubber device in the snubber assembly separate from the power module and/or a power module assembly. The process of the above-noted EXAMPLE includes configuring and arranging at least the snubber circuit in the snubber assembly separate from the power module and/or a power module assembly. The process of the above-noted EXAMPLE includes configuring and arranging at least the at least one snubber capacitor in the snubber assembly separate from the power module and/or a power module assembly. The process of the above-noted EXAMPLE includes configuring and arranging at least the at least one snubber capacitor outside and separate from a power module assembly. The process of the above-noted EXAMPLE includes configuring and arranging at least the snubber circuit outside and separate from a power module assembly. The process of the above-noted EXAMPLE includes configuring and arranging at least the snubber substrate at least partially within the snubber assembly. The process of the above-noted EXAMPLE includes configuring and arranging the at least one snubber capacitor within the snubber assembly. The process of the above-noted EXAMPLE includes configuring and arranging the snubber circuit within the snubber assembly. The process of the above-noted EXAMPLE where the power module comprises a power module assembly; and where the snubber device is configured to be arranged outside and separate from the power module assembly. The process of the above-noted EXAMPLE where the snubber substrate is configured as a heat sink. The process of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The process of the above-noted EXAMPLE where the snubber assembly is a housing. The process of the above-noted EXAMPLE where the snubber circuit is configured to be in thermal communication with the snubber substrate. The process of the above-noted EXAMPLE where the at least one snubber capacitor is configured to be in thermal communication with the snubber substrate. The process of the above-noted EXAMPLE where the at least one snubber capacitor is configured such that heat within the at least one snubber capacitor is transferred to the snubber substrate. The process of the above-noted EXAMPLE includes configuring and arranging the snubber device on a portion of a cold plate. The process of the above-noted EXAMPLE where the power module is configured to be arranged on a portion of the cold plate. The process of the above-noted EXAMPLE where the snubber device is configured such that heat within the snubber circuit is transferred to the snubber substrate and then to the cold plate. The process of the above-noted EXAMPLE where the snubber circuit is configured such that heat within the snubber circuit is transferred to the cold plate. The process of the above-noted EXAMPLE where the at least one snubber capacitor configured such that heat within the at least one snubber capacitor is transferred to the cold plate. The process of the above-noted EXAMPLE where the at least one snubber capacitor is configured such that heat within the at least one snubber capacitor is transferred to the snubber substrate and then to the cold plate. The process of the above-noted EXAMPLE where the snubber device is configured to connect to and/or further comprises power module interconnects configured to connect the snubber device to the power module. The process of the above-noted EXAMPLE where the power module interconnects are structured and configured to have lower inductance; and where the snubber circuit is configured to allow increased switching speeds for the power module. The process of the above-noted EXAMPLE where the power module interconnects are configured to connect the snubber device to power terminals of the power module. The process of the above-noted EXAMPLE where the snubber device is configured to connect to and/or further comprises a first power module interconnect and a second power module interconnect. The process of the above-noted EXAMPLE where the first power module interconnect is configured to connect the snubber device to a first power module terminal of the power module; and where the second power module interconnect is configured to connect to a second power module power terminal of the power module. The process of the above-noted EXAMPLE where the first power module interconnect and the second power module interconnect are configured to connect to the snubber circuit. The process of the above-noted EXAMPLE where the first power module interconnect and/or the second power module interconnect are implemented as busbars, wires, cables, and/or ribbons. The process of the above-noted EXAMPLE where the first power module interconnect and/or the second power module interconnect comprise buss bars. The process of the above-noted EXAMPLE includes at least a first power terminal and a second power terminal. The process of the above-noted EXAMPLE where the first power terminal is configured to connect to the first power module interconnect; and where the second power terminal is configured to connect to the second power module interconnect. The process of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The process of the above-noted EXAMPLE where the snubber device is configured to connect to and/or comprises capacitor interconnects that are configured to connect the snubber device to the at least one DC link capacitor. The process of the above-noted EXAMPLE where the capacitor interconnects are structured and configured to have lower inductance; and where the snubber circuit is configured to allow increased switching speeds for the power module. The process of the above-noted EXAMPLE where the snubber device is configured to connect to and/or comprises a first capacitor interconnect and a second capacitor interconnect. The process of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The process of the above-noted EXAMPLE where the first capacitor interconnect and/or the second capacitor interconnect, are implemented as busbars, wires, cables, and/or ribbons. The process of the above-noted EXAMPLE where the first capacitor interconnect and the second capacitor interconnect are configured to connect to the snubber circuit. The process of the above-noted EXAMPLE where the first capacitor interconnect and/or the second capacitor interconnect comprise buss bars. The process of the above-noted EXAMPLE includes a first capacitor terminal and a second capacitor terminal. The process of the above-noted EXAMPLE where the first capacitor terminal is configured to connect the snubber device to the first capacitor interconnect; and where the second capacitor terminal is configured to connect the snubber device to the second capacitor interconnect. The process of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The process of the above-noted EXAMPLE includes configuring and arranging the snubber substrate on a lower assembly surface of the snubber assembly. The process of the above-noted EXAMPLE where the snubber circuit is configured to allow increased switching speeds for the power module. The process of the above-noted EXAMPLE includes configuring and arranging the snubber circuit on an upper substrate surface of the snubber substrate. The process of the above-noted EXAMPLE includes configuring and arranging the at least one snubber capacitor on an upper substrate surface of the snubber substrate. The process of the above-noted EXAMPLE where the snubber circuit further comprises a resistor. The process of the above-noted EXAMPLE where the snubber circuit further comprises a diode. The process of the above-noted EXAMPLE where the snubber circuit further comprises a resistor and a diode. The process of the above-noted EXAMPLE where the power system is configured to provide power to an application.

One EXAMPLE: a process includes providing a snubber assembly. The process in addition includes providing a snubber circuit comprising at least one snubber capacitor. The process moreover includes providing a snubber substrate. The process also includes configuring and arranging the snubber device to connect to power module interconnects that connect the snubber device to the power module. The process further includes configuring and arranging the snubber device to connect to connect to capacitor interconnects that connect the snubber device to the at least one DC link capacitor.

The above-noted EXAMPLE may further include any one or a combination of more than one of the following EXAMPLES: The process of the above-noted EXAMPLE includes configuring and arranging at least the snubber circuit outside and separate from the power module. The process of the above-noted EXAMPLE includes configuring and arranging the snubber device outside and separate from the power module. The process of the above-noted EXAMPLE includes configuring and arranging at least the at least one snubber capacitor outside and separate from the power module. The process of the above-noted EXAMPLE includes configuring and arranging the snubber device in the snubber assembly separate from the power module and/or a power module assembly. The process of the above-noted EXAMPLE includes configuring and arranging at least the snubber circuit in the snubber assembly separate from the power module and/or a power module assembly. The process of the above-noted EXAMPLE includes configuring and arranging at least the at least one snubber capacitor in the snubber assembly separate from the power module and/or a power module assembly. The process of the above-noted EXAMPLE includes configuring and arranging at least the at least one snubber capacitor is configured to be arranged outside and separate from a power module assembly. The process of the above-noted EXAMPLE includes configuring and arranging at least the snubber circuit outside and separate from a power module assembly. The process of the above-noted EXAMPLE includes configuring and arranging at least the snubber substrate at least partially within the snubber assembly. The process of the above-noted EXAMPLE includes configuring and arranging the at least one snubber capacitor within the snubber assembly. The process of the above-noted EXAMPLE includes configuring and arranging the snubber circuit within the snubber assembly. The process of the above-noted EXAMPLE where the power module comprises a power module assembly; and where the snubber device is configured to be arranged outside and separate from the power module assembly. The process of the above-noted EXAMPLE where the snubber substrate is configured as a heat sink. The process of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The process of the above-noted EXAMPLE where the snubber assembly is a housing. The process of the above-noted EXAMPLE where the snubber circuit is configured to be in thermal communication with the snubber substrate. The process of the above-noted EXAMPLE where the at least one snubber capacitor is configured to be in thermal communication with the snubber substrate. The process of the above-noted EXAMPLE where the at least one snubber capacitor is configured such that heat within the at least one snubber capacitor is transferred to the snubber substrate. The process of the above-noted EXAMPLE includes configuring and arranging the snubber device on a portion of a cold plate. The process of the above-noted EXAMPLE includes configuring and arranging the power module is configured to be arranged on a portion of the cold plate. The process of the above-noted EXAMPLE where the snubber device is configured such that heat within the snubber circuit is transferred to the snubber substrate and then to the cold plate. The process of the above-noted EXAMPLE where the snubber circuit is configured such that heat within the snubber circuit is transferred to the cold plate. The process of the above-noted EXAMPLE where the at least one snubber capacitor configured such that heat within the at least one snubber capacitor is transferred to the cold plate. The process of the above-noted EXAMPLE where the at least one snubber capacitor is configured such that heat within the at least one snubber capacitor is transferred to the snubber substrate and then to the cold plate. The process of the above-noted EXAMPLE where the snubber device is configured to connect to and/or further comprises power module interconnects configured to connect the snubber device to the power module. The process of the above-noted EXAMPLE where the power module interconnects are structured and configured to have lower inductance; and where the snubber circuit is configured to allow increased switching speeds for the power module. The process of the above-noted EXAMPLE where the power module interconnects are configured to connect the snubber device to power terminals of the power module. The process of the above-noted EXAMPLE where the snubber device is configured to connect to and/or further comprises a first power module interconnect and a second power module interconnect. The process of the above-noted EXAMPLE where the first power module interconnect is configured to connect the snubber device to a first power module terminal of the power module; and where the second power module interconnect is configured to connect to a second power module power terminal of the power module. The process of the above-noted EXAMPLE where the first power module interconnect and the second power module interconnect are configured to connect to the snubber circuit. The process of the above-noted EXAMPLE where the first power module interconnect and/or the second power module interconnect are implemented as busbars, wires, cables, and/or ribbons. The process of the above-noted EXAMPLE where the first power module interconnect and/or the second power module interconnect comprise buss bars. The process of the above-noted EXAMPLE includes at least a first power terminal and a second power terminal. The process of the above-noted EXAMPLE where the first power terminal is configured to connect to the first power module interconnect; and where the second power terminal is configured to connect to the second power module interconnect. The process of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The process of the above-noted EXAMPLE where the snubber device is configured to connect to and/or comprises capacitor interconnects that are configured to connect the snubber device to the at least one DC link capacitor. The process of the above-noted EXAMPLE where the capacitor interconnects are structured and configured to have lower inductance; and where the snubber circuit is configured to allow increased switching speeds for the power module. The process of the above-noted EXAMPLE where the snubber device is configured to connect to and/or comprises a first capacitor interconnect and a second capacitor interconnect. The process of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The process of the above-noted EXAMPLE where the first capacitor interconnect and/or the second capacitor interconnect, are implemented as busbars, wires, cables, and/or ribbons. The process of the above-noted EXAMPLE where the first capacitor interconnect and the second capacitor interconnect are configured to connect to the snubber circuit. The process of the above-noted EXAMPLE where the first capacitor interconnect and/or the second capacitor interconnect comprise buss bars. The process of the above-noted EXAMPLE includes a first capacitor terminal and a second capacitor terminal. The process of the above-noted EXAMPLE where the first capacitor terminal is configured to connect the snubber device to the first capacitor interconnect; and where the second capacitor terminal is configured to connect the snubber device to the second capacitor interconnect. The process of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The process of the above-noted EXAMPLE includes configuring and arranging the snubber substrate on a lower assembly surface of the snubber assembly. The process of the above-noted EXAMPLE where the snubber circuit is configured to allow increased switching speeds for the power module. The process of the above-noted EXAMPLE includes configuring and arranging the snubber circuit on an upper substrate surface of the snubber substrate. The process of the above-noted EXAMPLE includes configuring and arranging the at least one snubber capacitor on an upper substrate surface of the snubber substrate. The process of the above-noted EXAMPLE where the snubber circuit further comprises a resistor. The process of the above-noted EXAMPLE where the snubber circuit further comprises a diode. The process of the above-noted EXAMPLE where the snubber circuit further comprises a resistor and a diode. The process of the above-noted EXAMPLE where the power system is configured to provide power to an application.

One EXAMPLE: a process includes providing a snubber assembly. The process in addition includes providing a snubber circuit comprising at least one snubber capacitor. The process moreover includes providing a snubber substrate. The process also includes configuring and arranging at least the at least one snubber capacitor outside and separate from the power module.

The above-noted EXAMPLE may further include any one or a combination of more than one of the following EXAMPLES: The process of the above-noted EXAMPLE includes configuring and arranging the snubber device outside and separate from the power module. The process of the above-noted EXAMPLE includes configuring and arranging includes configuring and arranging at least the snubber circuit outside and separate from the power module. The process of the above-noted EXAMPLE includes configuring and arranging the snubber device in the snubber assembly separate from the power module and/or a power module assembly. The process of the above-noted EXAMPLE includes configuring and arranging at least the snubber circuit in the snubber assembly separate from the power module and/or a power module assembly. The process of the above-noted EXAMPLE includes configuring and arranging at least the at least one snubber capacitor in the snubber assembly separate from the power module and/or a power module assembly. The process of the above-noted EXAMPLE includes configuring and arranging at least the at least one snubber capacitor outside and separate from a power module assembly. The process of the above-noted EXAMPLE includes configuring and arranging at least the snubber circuit outside and separate from a power module assembly. The process of the above-noted EXAMPLE includes configuring and arranging at least the snubber substrate at least partially within the snubber assembly. The process of the above-noted EXAMPLE includes configuring and arranging the at least one snubber capacitor within the snubber assembly. The process of the above-noted EXAMPLE includes configuring and arranging the snubber circuit within the snubber assembly. The process of the above-noted EXAMPLE where the power module comprises a power module assembly; and where the snubber device outside and separate from the power module assembly. The process of the above-noted EXAMPLE includes configuring the snubber substrate as a heat sink. The process of the above-noted EXAMPLE where the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS). The process of the above-noted EXAMPLE where the snubber assembly is a housing. The process of the above-noted EXAMPLE includes configuring the snubber circuit to be in thermal communication with the snubber substrate. The process of the above-noted EXAMPLE includes configuring the at least one snubber capacitor to be in thermal communication with the snubber substrate. The process of the above-noted EXAMPLE includes configuring the at least one snubber capacitor such that heat within the at least one snubber capacitor is transferred to the snubber substrate. The process of the above-noted EXAMPLE includes configuring and arranging the snubber device on a portion of a cold plate. The process of the above-noted EXAMPLE includes configuring and arranging the power module on a portion of the cold plate. The process of the above-noted EXAMPLE includes configuring the snubber device such that heat within the snubber circuit is transferred to the snubber substrate and then to the cold plate. The process of the above-noted EXAMPLE includes configuring the snubber circuit such that heat within the snubber circuit is transferred to the cold plate. The process of the above-noted EXAMPLE includes configuring the at least one snubber capacitor such that heat within the at least one snubber capacitor is transferred to the cold plate. The process of the above-noted EXAMPLE includes configuring the at least one snubber capacitor such that heat within the at least one snubber capacitor is transferred to the snubber substrate and then to the cold plate. The process of the above-noted EXAMPLE where the snubber device is configured to connect to and/or further comprises power module interconnects configured to connect the snubber device to the power module. The process of the above-noted EXAMPLE where the power module interconnects are structured and configured to have lower inductance; and where the snubber circuit is configured to allow increased switching speeds for the power module. The process of the above-noted EXAMPLE where the power module interconnects are configured to connect the snubber device to power terminals of the power module. The process of the above-noted EXAMPLE where the snubber device is configured to connect to and/or further comprises a first power module interconnect and a second power module interconnect. The process of the above-noted EXAMPLE where the first power module interconnect is configured to connect the snubber device to a first power module terminal of the power module; and where the second power module interconnect is configured to connect to a second power module power terminal of the power module. The process of the above-noted EXAMPLE where the first power module interconnect and the second power module interconnect are configured to connect to the snubber circuit. The process of the above-noted EXAMPLE where the first power module interconnect and/or the second power module interconnect are implemented as busbars, wires, cables, and/or ribbons. The process of the above-noted EXAMPLE where the first power module interconnect and/or the second power module interconnect comprise buss bars. The process of the above-noted EXAMPLE includes at least a first power terminal and a second power terminal. The process of the above-noted EXAMPLE where the first power terminal is configured to connect to the first power module interconnect; and where the second power terminal is configured to connect to the second power module interconnect. The process of the above-noted EXAMPLE includes: a power connection connecting the first power terminal and the first power module interconnect to the snubber circuit and/or the at least one snubber capacitor; and a power connection connecting the second power terminal and the second power module interconnect to the snubber circuit and/or the at least one snubber capacitor. The process of the above-noted EXAMPLE where the snubber device is configured to connect to and/or comprises capacitor interconnects that are configured to connect the snubber device to the at least one DC link capacitor. The process of the above-noted EXAMPLE where the capacitor interconnects are structured and configured to have lower inductance; and where the snubber circuit is configured to allow increased switching speeds for the power module. The process of the above-noted EXAMPLE where the snubber device is configured to connect to and/or comprises a first capacitor interconnect and a second capacitor interconnect. The process of the above-noted EXAMPLE where the first capacitor interconnect is configured to connect the snubber device to a first capacitor terminal of the at least one DC link capacitor; and where the second capacitor interconnect is configured to connect to a second capacitor terminal of the at least one DC link capacitor. The process of the above-noted EXAMPLE where the first capacitor interconnect and/or the second capacitor interconnect, are implemented as busbars, wires, cables, and/or ribbons. The process of the above-noted EXAMPLE where the first capacitor interconnect and the second capacitor interconnect are configured to connect to the snubber circuit. The process of the above-noted EXAMPLE where the first capacitor interconnect and/or the second capacitor interconnect comprise buss bars. The process of the above-noted EXAMPLE includes a first capacitor terminal and a second capacitor terminal. The process of the above-noted EXAMPLE where the first capacitor terminal is configured to connect the snubber device to the first capacitor interconnect; and where the second capacitor terminal is configured to connect the snubber device to the second capacitor interconnect. The process of the above-noted EXAMPLE includes: a power connection connecting the first capacitor terminal and the first capacitor interconnect to the snubber circuit and/or the at least one snubber capacitor; and a power connection connecting the second capacitor terminal and the second capacitor interconnect to the snubber circuit and/or the at least one snubber capacitor. The process of the above-noted EXAMPLE includes configuring and arranging the snubber substrate on a lower assembly surface of the snubber assembly. The process of the above-noted EXAMPLE where the snubber circuit is configured to allow increased switching speeds for the power module. The process of the above-noted EXAMPLE includes configuring and arranging the snubber circuit on an upper substrate surface of the snubber substrate. The process of the above-noted EXAMPLE includes configuring and arranging the at least one snubber capacitor on an upper substrate surface of the snubber substrate. The process of the above-noted EXAMPLE where the snubber circuit further comprises a resistor. The process of the above-noted EXAMPLE where the snubber circuit further comprises a diode. The process of the above-noted EXAMPLE where the snubber circuit further comprises a resistor and a diode. The process of the above-noted EXAMPLE includes configuring the power system to provide power to an application.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A snubber device configured to be implemented in a power system, the power system comprising a power module and at least one DC link capacitor, the snubber device comprising:
a snubber assembly;
a snubber circuit comprising at least one snubber capacitor; and
a snubber substrate,
wherein the snubber assembly is configured to be arranged outside and separate from the power module.

2.-6. (canceled)

7. The snubber device according to claim 1 wherein at least the snubber substrate is at least partially configured and arranged within the snubber assembly.

8. The snubber device according to claim 1 wherein the at least one snubber capacitor is configured and arranged within the snubber assembly.

9. The snubber device according to claim 1 wherein the snubber circuit is configured and arranged within the snubber assembly.

10. The snubber device according to claim 1
wherein the power module comprises a power module assembly; and
wherein the snubber device is configured to be arranged outside and separate from the power module assembly.

11. The snubber device according to claim 1 wherein the snubber substrate is configured as a heat sink.

12. The snubber device according to claim 1 wherein the snubber substrate comprises an active metal braze (AMB) substrate, a direct bond copper (DBC) substrate, a direct copper bonded (DCB) substrate, a direct printed copper (DPC) substrate, and/or an insulated metal substrate (IMS).

13. The snubber device according to claim 1 wherein the snubber assembly is a housing.

14. The snubber device according to claim 1 wherein the snubber circuit is configured to be in thermal communication with the snubber substrate.

15. The snubber device according to claim 1 wherein the at least one snubber capacitor is configured to be in thermal communication with the snubber substrate.

16. The snubber device according to claim 1 wherein the at least one snubber capacitor is configured such that heat within the at least one snubber capacitor is transferred to the snubber substrate.

17. The snubber device according to claim 1 wherein the snubber device is configured to be arranged on a portion of a cold plate.

18. The snubber device according to claim 17 wherein the power module is configured to be arranged on a portion of the cold plate.

19. The snubber device according to claim 17 wherein the snubber device is configured such that heat within the snubber circuit is transferred to the snubber substrate and then to the cold plate.

20.-22. (canceled)

23. The snubber device according to claim 1 wherein the snubber device is configured to connect to and/or further comprises power module interconnects configured to connect the snubber device to the power module.

24. The snubber device according to claim 23
wherein the power module interconnects are structured and configured to have lower inductance; and
wherein the snubber circuit is configured to allow increased switching speeds for the power module.

25. The snubber device according to claim 23 wherein the power module interconnects are configured to connect the snubber device to power terminals of the power module.

26. The snubber device according to claim 1 wherein the snubber device is configured to connect to and/or further comprises a first power module interconnect and a second power module interconnect.

27. The snubber device according to claim 26
wherein the first power module interconnect is configured to connect the snubber device to a first power module terminal of the power module; and
wherein the second power module interconnect is configured to connect to a second power module power terminal of the power module.

28. The snubber device according to claim 26 wherein the first power module interconnect and the second power module interconnect are configured to connect to the snubber circuit.

29. The snubber device according to claim 26 wherein the first power module interconnect and/or the second power module interconnect are implemented as busbars, wires, cables, and/or ribbons.

30. The snubber device according to claim 26 wherein the first power module interconnect and/or the second power module interconnect comprise buss bars.

31. The snubber device according to claim 1 wherein the snubber device is configured to connect to and/or comprises capacitor interconnects that are configured to connect the snubber device to the at least one DC link capacitor.

32. The snubber device according to claim 31
wherein the capacitor interconnects are structured and configured to have lower inductance; and
wherein the snubber circuit is configured to allow increased switching speeds for the power module.

33.-44. (canceled)

45. The snubber device according to claim 1 wherein the snubber substrate is configured to be arranged on a lower assembly surface of the snubber assembly.

46. The snubber device according to claim 1 wherein the snubber circuit is configured to be arranged on an upper substrate surface of the snubber substrate.

47.-51. (canceled)

52. A snubber device configured to be implemented in a power system, the power system comprising a power module and at least one DC link capacitor, the snubber device comprising:
a snubber assembly;
a snubber circuit comprising at least one snubber capacitor; and
a snubber substrate,
wherein the snubber device is configured to connect to power module interconnects that connect the snubber device to the power module; and
wherein the snubber device is configured to connect to capacitor interconnects that connect the snubber device to the at least one DC link capacitor.

53.-105. (canceled)

106. A snubber device configured to be implemented in a power system, the power system comprising a power module and at least one DC link capacitor, the snubber device comprising:
a snubber assembly;
a snubber circuit comprising at least one snubber capacitor; and
a snubber substrate,
wherein at least the at least one snubber capacitor is configured to be arranged outside and separate from the power module.

107.-316. (canceled)
